(19) United States
(12) Patent Application Publication
(10) Pub. No.: US 2014/0139365 A1
(43) Pub. Date: May 22, 2014

(54) SYSTEM FOR RNS BASED ANALOG-TO-DIGITAL CONVERSION AND INNER PRODUCT COMPUTATION

(71) Applicants: Chan Hua Vun, Singapore (SG); Benjamin Premkumar, Singapore (SG)

(72) Inventors: Chan Hua Vun, Singapore (SG); Benjamin Premkumar, Singapore (SG)

(21) Appl. No.: 14/130,051

(22) PCT Filed: May 7, 2012
(86) PCT No.: PCT/SG2012/000160

§ 371 Date: Dec. 30, 2013

Related U.S. Application Data
(60) Provisional application No. 61/502,869, filed on Jun. 30, 2011.

(51) Int. Cl. H03M 1/34

(52) U.S. Cl. CPC H03M 1/345
USPC 341/155

(57) ABSTRACT

A system is proposed for forming the inner product of an input signal having a number of signal entries, with a pre-known vector. Each signal entry is represented in an RNS format. The residue for each modulus is represented as a string in which the number of components taking a first value is equal to the residue. Corresponding components of the strings for different input entries are used to obtain a summation value, and the summation values are accumulated. Since the components of the string are not associated with weight values, the accumulation of the summation values can be performed without using a scaling accumulator. Furthermore, an ADC is proposed which uses the input signal to generate an RNS representation of the signal based on a plurality of moduli. For each modulus, there is a corresponding Residue Number System (RNS) converter which includes a number of zero-crossing-based folding circuits equal to the modulus, and a comparator for each zero-crossing based folding circuit. The output of the comparators is used to form the RNS representation. This ADC is efficient in terms of the number of comparators it uses. Optionally, the RNS representation may be converted into a different digital representation.

### FIELD OF THE INVENTION

The present invention relates to a computation system for computing an inner product of an input signal with a plurality of coefficients, and to an analog-to-digital converter (ADC). The ADC may be employed as a component of the computation system. The ADC is based on the Residue Number System, which on its own, is capable of providing a highly efficient way of implementing high resolution high speed analog to digital conversion. The computation system for computing the inner product is based on the Residue Number System and Distributed Arithmetic technique and works especially well with the ADC.

### BACKGROUND OF THE INVENTION

Many applications require the digitization of an analog signal, followed by digital signal processing, often involving the computation of an inner product of a vector representing the digitized signal with another vector.

### Analog-to-Digital Converters

The Flash ADC is the most common solid-state circuit based high speed ADC in use today. In the Flash ADC, multiple parallel comparators, equal to the number of quantization levels to resolute, are used to convert the analog input signal to the corresponding digital output (comprising a plurality of input signal entries). A Flash ADC in the form of a parallel converter of n-bit resolution provides a 2ⁿ dynamic range and has 2ⁿ−1 quantization levels (a quantization level is also known as the least significant bit, LSB) and hence requires a total of 2ⁿ−1 parallel comparators. For instance, an 8-bit parallel type Flash ADC will need 2⁸−1=255 parallel comparators. Since the number of parallel comparators needed increases exponentially with the resolution, managing the skew times between the parallel paths used by the parallel comparators in higher resolution high speed Flash ADCs becomes a complicated issue. Furthermore, the overall power dissipation and chip area required also increase tremendously with the number of parallel paths in a Flash ADC. These factors impose a practical limit to the resolution that can be achieved in these types of high speed Flash ADCs.

A high-speed alternative to the Flash ADC is the Folding ADC. Operation of a Folding ADC is similar to a two-step ADC. In particular, both the Folding ADC and the two-step ADC comprise two parts: a coarse quantizer to output the MSBs (most significant bits), and a fine quantizer to digitize the residual signal (i.e. signal remaining after removing the MSBs) and output the LSBs. However, in a Folding ADC, the residual signal is obtained directly from a folding circuit. This is unlike the two-step ADC that obtains the residual signal through the output of its coarse quantizer. As such, the Folding ADC can operate at the full speed of a Flash ADC without the need to wait for the coarse quantizer to first complete its operation.

A Folding ADC uses fewer parallel paths than a Flash ADC but is capable of retaining the high speed of the Flash ADC. With the Folding ADC, the number of parallel paths is reduced significantly and is minimized when the MSBs and the LSBs have the same number of bits. For example, an 8-bit Folding ADC having 4-bit MSBs and 4-bit LSBs will require only 2(2⁴−1)=30 parallel comparators. This is much less than the 255 comparators required in an 8-bit Flash ADC.

The operation of the Folding ADC is discussed in greater detail in reference [10].

### Inner Product Computation

Inner product computation of a signal with a plurality of coefficients is required in the fundamental function of many digital signal processing applications. Therefore, its implementation efficiency is of major significance from a practical feasibility point of view.

The Distributed Arithmetic (DA) technique is a well-known technique for computing inner products [1]. Compared to the multiply-accumulate (MAC) approach, the DA technique allows the inner product computation to be completed in a number of cycles proportional to the bit-length of the input signal entries, instead of the number of coefficients. As such, it provides performance gain when the number of coefficients is more than the bit-length of the input signal entries. Inner product computation involves the addition of a series of products (i.e. multiplication outputs). The DA technique allows the computation of the inner products without the need to perform multiplication by using a look up table (LUT) with bit-serial data addressing to provide the products. These products are then added together to derive the final answer i.e. the inner product.

### Residue Number System

The Residue Number System (RNS) [2] is suitable for the implementation of high speed digital signal processing as parallel operations and small data bit-lengths may be achieved with the RNS.

In the RNS, a big natural number A within a legitimate dynamic range [0,P) can be uniquely represented by a set of smaller natural numbers <a₁,a₂, . . . , a_{M}>. This set of smaller natural numbers is known as the residues or residue digits of the number A and is derived based on a modular arithmetic principle using a selected set of numbers [m₁,m₂, . . . , m_{M}] called the moduli set. In particular, this set of smaller natural numbers <a₁,a₂, . . . , a_{M}> are remainders obtained by dividing the number A by the moduli [m₁,m₂, . . . , m_{M}]. The moduli are pair-wise prime positive integers (that is, they have no integer factors in common except 1) and P is equal to the product of the moduli, i.e. A<P=πᵢ₌₁^{M}mᵢ. The relationship between the number A and its residues <a₁,a₂, . . . , a_{M}> may be referred to as a RNS relationship which may be expressed in the form A≅<a₁,a₂, . . . , a_{M}>. Furthermore, the residues <a₁,a₂, . . . , a_{M}> of a number A are referred to as the RNS format of the number A.

Besides being able to represent a big natural number using smaller residue digits, another important property of the RNS is that arithmetic operations such as addition, subtraction and multiplication of two numbers A and B can be equivalently performed with RNS-based arithmetic using their corresponding sets of residue digits aᵢ and bᵢ corresponding to the modulus mᵢ. Moreover, these operations can be performed in an independent and parallel manner, with no carry-propagation occurring between the operations for different moduli.

For instance, using the [7,8,9] moduli set which provide a legitimate dynamic range of [0,504), the integer R=179 can be represented by the residue digits 4, 3 and 8 (i.e. [symbol] 4,3,8 [symbol] _{7,8,9} residue set) and the integer S=254 can be represented by the [symbol] 2,6,2 [symbol] _{7,8,9} residue set. Arithmetic operations between the integers R and S can be equivalently performed using their corresponding residue sets [symbol] 4,3,8 [symbol] _{7,8,9} and [symbol] 2,6,2 [symbol] _{7,8,9} as follows:

$$179 \cdot 254 ≅ {〈 4 , 3 , 8 〉}_{7 , 8 , 9} \cdot {〈 2 , 6 , 2 〉}_{7 , 8 , 9} = {〈 4 \cdot 2 , 3 \cdot 6 , 8 \cdot 2 〉}_{7 , 8 , 9} \qquad ( 1 )$$

where the arithmetic operator ∘ can be +, − or ×.

For example, with the arithmetic operator ∘ as +, the following is obtained.

$$179 + 254 ≅ {〈 4 , 3 , 8 〉}_{7 , 8 , 9} + {〈 2 , 6 , 2 〉}_{7 , 8 , 9} = {〈 4 + 2 , 3 + 6 , 8 + 2 〉}_{7 , 8 , 9} = {〈 6 , 9 , 10 〉}_{7 , 8 , 9} = {〈 6 , 1 , 1 〉}_{7 , 8 , 9} \qquad ( 2 )$$

Note that there is a need to perform a modulo operation on an output of the arithmetic operation if its value exceeds its modulus. For example, in Equation (2), the outputs of the arithmetic operation “+” on the residue digits are 6, 9 and 10 expressed in the form (6,9,10)_{7,8,9}. Outputs 9 and 10 exceed their corresponding moduli 8 and 9 and thus, it is necessary to perform modulo operations on outputs 9 and 10 with moduli 8 and 9 respectively.

### Residue Number System for Inner Product Calculation

As shown in Equation (2), in the RNS, arithmetic operations between residue digits arising from the same modulus can be performed in a parallel and independent manner from residue digits arising from other moduli. This is as long as the resultant output from the arithmetic operation does not exceed the legitimate dynamic range provided by the moduli set. Furthermore, since the residue digits of a number are smaller than the number itself, a much shorter bit-length may be used to encode the residue digits as compared to the bit-length used to encode the number. These properties of the RNS i.e. smaller residue digits and parallel arithmetic operations make the RNS ideal for use with the DA technique for inner product calculation. In particular, since the performance gain that can be provided by the DA technique is dependent on the bit-lengths of the input signal entries, the smaller values of the residue digits can lead to a faster execution cycle due to the shorter bit-lengths required to encode the residue digits. Furthermore, the ability for parallel operations across different moduli enable simultaneous arithmetic operations to be done in multiple independent channels, each reserved for residue digits derived using the same modulus.

However, in practice, some complications arise when implementing the RNS with the DA technique (i.e. when implementing a DA-RNS system) for inner product calculation. Even if each input signal entry is in the RNS format with smaller residue digits, the residue digits themselves are usually still encoded in the binary code (BC) format. As such, there are still overheads (although, lower when compared to using a non-RNS based approach) due to localized carry propagation in the arithmetic operations performed in each channel. Furthermore, because of the 2ⁿ bit weights associated with the BC format, a 2ⁿ scaling process is required for the inner product computation when the residue digits are encoded in the BC format. This need for a 2ⁿ scaling process complicates issues in a DA-RNS system for inner product computation since executing a modulo operation on the 2ⁿ factor is complex in practice [3]. Therefore, in a DA-RNS system using the BC format to encode the residue digits (i.e. a BC based DA-RNS system), the modular adder used to compute the inner products requires a convoluted implementation. There is also no simple way to perform the modulo operation [2] for BC formatted residue digits for a generic class of moduli (i.e. not moduli with carefully selected values, such as powers of 2 or the like). Thus, to date, there are hardly any reports on efficient means to implement the DA-RNS concept.

The following provides more details of the DA technique and the BC based DA-RNS system.

### Distributed Arithmetic for Inner Product Computation—Da Technique

Inner product computation of an input signal with a plurality of coefficients Aₖ may be expressed as follows:

$$y = {\sum }_{k = 0}^{K - 1} {A}_{k} {x}_{k} \qquad ( 3 )$$

In Equation (3), y is the inner product to be computed and it is assumed that Aₖ take on fixed values (e.g. Aₖ may be the filter coefficients of a FIR filter). The input signal is in a representation x̅ₖ=[x₀,x₁, . . . , x_{K-1}] which is an input vector comprising a plurality of (K) input signal entries x₀,x₁, . . . , x_{K-1}. Using the standard multiply and accumulate (MAC) approach, the calculation of this inner product will take K cycles, corresponding to the number of coefficients Aₖ.

Now consider the case whereby each input signal entry xₖ is encoded with a plurality of bits in the BC format with a bit-length of N. Each input signal entry xₖ may be expressed in terms of its plurality of bits bₖₙ as follows:

$${x}_{k} = {\sum }_{n = 0}^{N - 1} {b}_{kn} {2}^{n} \qquad ( 4 )$$

In Equation (4), bₖₙ represents the bit in the n^{th} bit position (i.e. the n^{th} bit) of the plurality of bits encoding xₖ and has either the binary value of 0 or 1 (i.e. is either bit ‘0’ or bit ‘1’). 2ⁿ represents the weight of the bit bₖₙ and differs for each bit bₖₙ.

Substituting Equation (4) into Equation (3), Equation (3) can be written in the form associated directly with the bits of the input signal entries as follows:

$$y = {\sum }_{k = 0}^{K - 1} {A}_{k} {x}_{k} = {\sum }_{k = 0}^{K - 1} {A}_{k} {\sum }_{n = 0}^{N - 1} {b}_{kn} {2}^{n} \qquad ( 5 )$$

Interchanging the order of the summations in Equation (5) and bringing Aₖ together with the binary bits bₖₙ of xₖ, the following equation is obtained.

$$\begin{matrix}y = {\sum }_{n = 0}^{N - 1} \{ {\sum }_{k = 0}^{K - 1} {A}_{k} {b}_{kn} \} {2}^{n} & ( 6 ) \\ Let f ( {A}_{k} , {b}_{kn} ) = {\sum }_{k = 0}^{K - 1} {A}_{k} {b}_{kn} & ( 7 ) \\ Hence y = {\sum }_{n = 0}^{N - 1} f ( {A}_{k} , {b}_{kn} ) {2}^{n} & ( 8 )\end{matrix}$$

The function f(Aₖ,bₖₙ) represents a sum of multiplications to be performed and is derived using the individual binary bits bₖₙ of each input signal entry xₖ. Since each bit bₖₙ can only take on a value of either 0 or 1 and the value of each Aₖ is fixed, there are altogether 2^{K} possible combinations of the bits bₖₙ and the coefficients Aₖ for Equation (7).

In the DA technique, the values of the function f(Aₖ,bₖₙ) resulting from the 2^{K} possible combinations may be pre-computed and stored as entries in a Look-Up-Table (DALUT). The DALUT is then successively addressed by using the n^{th} bit of all the input signal entries xₖ in parallel, starting with n=0 until n=N−1. With each addressing of the DALUT, an output comprising the value of the function f(Aₖ,bₖₙ) corresponding to the n^{th} bit is provided. The successive outputs from the DALUT are then accumulated as indicated in Equation (8) and the eventual N−1 accumulated sum is the inner product y. From Equation (8), it can be seen that due to the different weights 2ⁿ of the binary bits bₖₙ in the input signal entries xₖ, there is a need to first scale each output from the DALUT by its respective 2ⁿ factor.

Consider an example of K=4 inner product computation having four coefficients. This inner product computation has the expression shown in Equation (9) below:

$$\begin{matrix}y = {\sum }_{k = 0}^{3} {A}_{k} {x}_{k} \\ = {A}_{0} {x}_{0} + {A}_{1} {x}_{1} + {A}_{2} {x}_{2} + {A}_{3} {x}_{3}\end{matrix} \qquad ( 9 )$$

In this example, each of the input signal entries xₖ: x₀,x₁,x₂,x₃ is encoded with a plurality of bits bₖₙ in the BC format with a bit-length of N=3 as follows:

x₀={b₀₂b₀ₗb₀₀}

x₁={b₁₂b₁ₗb₁₀}

x₂={b₂₂b₂ₗb₂₀}

x₃={b₃₂b₃ₗb₃₀} (10)

A system based on the DA technique (i.e. BC based DA system) can then be implemented. FIG. 1 shows a BC based DA system for computing an inner product of the input signal with the coefficients Aₖ in this example. As shown in FIG. 1, there are 2⁴=16 entries in the DALUT with their values derived using Equation (5).

The DALUT is then successively addressed using the n^{th} bit of all the input signal entries xₖ in parallel, starting with n=0 until n=2 and the corresponding DALUT entries are successively provided as DALUT's outputs. This takes places in three execution cycles whereby in each execution cycle, a collective bit pattern formed by concatenating the n^{th} bit of the input signal entries in a bit-serial manner is used. The collective bit patterns bₖ₀, bₖ₁ and bₖ₂ (with k=0 to 3) respectively for the execution cycles t_{cycle}=0, t_{cycle}=1 and t_{cycle}=2 are as follows:

t_{cycle}=0:bₖ₀={b₀₀b₁₀b₂₀b₃₀}

t_{cycle}=1:bₖ₁={b₀₁b₁₁b₂₁b₃₁}

t_{cycle}=2:bₖ₂={b₀₂b₁₂b₂₂b₃₂} (11)

The DALUT output from each execution cycle is then scaled by its corresponding scaling factor 2ⁿ before it is accumulated with scaled DALUT outputs from previous execution cycles (see Equation (8)).

In a conventional binary number system, the 2ⁿ scaling of a DALUT output may be performed by a logical left shift of the bits of the DALUT output by an amount corresponding to the value of n. The adder can be any type of binary adder and the output of the adder may be stored into a register to be used for further accumulation with incoming scaled DALUT outputs.

Assuming that the scaling and accumulation execution operations for each DALUT output can be performed within one clock cycle (although, in practice, depending on the accumulator implementation, this may take more than 1 clock cycle), the inner product computation can thus be completed in N clock cycles with the DA technique. In contrast, using the MAC approach, the computation will take K execution cycles. Assuming that each MAC execution operation can be performed within one clock cycle (which is only true if one multiplication and addition can be performed in 1 cycle), the DA technique provides performance gain for the inner product computation if N<K. This is the case in the above example where N=3 and K=4. In practice, the value of N is usually much lower than that of K, i.e. N<<K. Furthermore, there is no multiplier needed in the DA technique to perform the computation due to the use of the DALUT. This is beneficial as having a multiplier is typically more hardware costly.

### Binary Code (BC) Based DA-RNS System

BC based DA-RNS systems have been reported in publications such as [3], [5] and [6] but the number of publications are fewer than what one would normally expect in view of such a seemingly good match between the DA technique and the RNS. This is likely due to the difficulties in implementing modulo operations on the 2ⁿ scaling factors that originate from the weights of the bits of the BC encoded residues (BCR). The following derives the expression reflecting the implementation of the inner product computation using the RNS and DA technique, and reveals the above-mentioned difficulties.

Starting with the same inner product computation expression as in Equation (3) whereby

$$y = {\sum }_{k = 0}^{K - 1} {A}_{k} {x}_{k}$$

and expressing y in its RNS format y≅ [symbol] y₁,y₂, . . . , y_{M} [symbol] using a [m₁,m₂, . . . , m_{M}] moduli set, a total of M residue digits based equations can be derived. Each residue digits based equation has the general expression as shown in Equation (12) where yᵢ is the inner product for the modulus mᵢ.

$$\begin{matrix}{y}_{i} = {\vert {\sum }_{k = 0}^{K - 1} {A}_{k} {y}_{k} \vert}_{{m}_{i}} \\ = {\vert {\sum }_{k = 0}^{K - 1} \{ {\vert {A}_{k} \vert}_{{m}_{i}} {\vert {x}_{k} \vert}_{{m}_{i}} \} \vert}_{{m}_{i}}\end{matrix} \qquad ( 12 )$$

Using the binary bit representation of xₖ as given in Equation (4), |xₖ|ₘ_{ᵢ} becomes

$${\vert {x}_{k} \vert}_{{m}_{i}} = {\vert {\sum }_{n = 0}^{N - 1} {b}_{kn} {2}^{n} \vert}_{{m}_{i}} \qquad ( 13 )$$

Combining Equations (12) and (13) produces

$$\begin{matrix}{y}_{i} = {\vert {\sum }_{k = 0}^{K - 1} \{ {\vert {A}_{k} \vert}_{{m}_{i}} {\vert {\sum }_{n = 0}^{N - 1} {b}_{kn} {2}^{n} \vert}_{{m}_{i}} \} \vert}_{{m}_{i}} \\ = {\vert {\sum }_{k = 0}^{K - 1} \{ {\vert {A}_{k} {\sum }_{n = 0}^{N - 1} {b}_{kn} {2}^{n} \vert}_{{m}_{i}} \} \vert}_{{m}_{i}} \\ = {\vert {\sum }_{k = 0}^{K - 1} {A}_{k} {\sum }_{n = 0}^{N - 1} {b}_{kn} {2}^{n} \vert}_{{m}_{i}}\end{matrix} \qquad ( 14 )$$

The expression within the modulus of Equation (14) is the same as that in Equation (5), and hence can be similarly re-arranged as follows:

$$\begin{matrix}{y}_{i} = {\vert {\sum }_{n = 0}^{N - 1} \{ {\sum }_{k = 0}^{K - 1} {A}_{k} {b}_{kn} \} {2}^{n} \vert}_{{m}_{i}} \\ = {\vert {\sum }_{n = 0}^{N - 1} f ( {A}_{k} , {b}_{kn} ) {2}^{n} \vert}_{{m}_{i}}\end{matrix} \qquad ( 15 )$$

As before, the 2ⁿ factor needs to be decoupled from the term f(Aₖ,bₖₙ) that is to be stored in the DALUT. This is done by applying the algebra of RNS as follows

$$\begin{matrix}{y}_{i} = \vert {\sum }_{n = 0}^{N - 1} \vert {\vert f ( {A}_{k} , {b}_{kn} ) \vert}_{{m}_{i}} {\vert {2}^{n} \vert}_{{m}_{i}} {{\vert}_{{m}_{i}} \vert}_{{m}_{i}} \\ Let & ( 16 ) \\ {f}_{{m}_{i}} ( {A}_{k} , {b}_{kn} ) = {\vert f ( {A}_{k} , {b}_{kn} ) \vert}_{{m}_{i}} = {\vert {\sum }_{k = 0}^{K - 1} {A}_{k} {b}_{kn} \vert}_{{m}_{i}} & ( 17 )\end{matrix}$$

Equation (16) then becomes the residue expression:

$${y}_{i} = \vert {\sum }_{n = 0}^{N - 1} \vert {f}_{{m}_{i}} ( {A}_{k} , {b}_{kn} ) {\vert {2}^{n} \vert}_{{m}_{i}} {{\vert}_{{m}_{i}} \vert}_{{m}_{i}} \qquad ( 18 )$$

The values of fₘ_{ᵢ}(Aₖ,bₖₙ) can be stored in the DALUT and can be subsequently clocked out by using bit-serial streams with the n^{th} bits of the input signal entries for the accumulation operation as described above. Note that each value of fₘ_{ᵢ}(Aₖ,bₖₙ) needs to be scaled with a |2ⁿ|ₘ_{ᵢ} factor before it is accumulated with other scaled values of fₘ_{ᵢ}(Aₖ,bₖₙ) from previous execution cycles. It is difficult to implement this scaling due to the complexity of the modulo operation on 2ⁿ based on mᵢ.

FIG. 2 shows an example hardware circuitry [3] needed to implement the accumulator 202 for the scaling and accumulation operations in a BC based DA-RNS system. FIG. 2 illustrates the complications faced in implementing the accumulator 202 in practice. In other words, it is difficult to perform inner product calculation with a BC based DA-RNS system.

### SUMMARY OF THE INVENTION

The present invention aims, in one aspect, to provide a new and useful converter for converting an analog input signal into a digital representation.

In general terms, the one aspect of the present invention proposes an ADC which uses the input signal to generate an RNS representation of the signal based on a plurality of moduli. For each modulus there is a Residue Number System (RNS) converter which includes a number of zero-crossing based folding circuits equal to the modulus, and a comparator for each zero-crossing based folding circuit. The output of the comparators is used to form the RNS representation. This ADC may be implemented using a smaller number of comparators than known systems, and with high accuracy. Optionally, the RNS representation may be converted into different digital representations.

The present invention further aims, in another aspect, to provide a new and useful system for computing an inner product of an input signal with a plurality of coefficients.

In general terms, the other aspect of the present invention proposes a system which uses the input signal having a number K of signal entries. Each signal entry is represented in an RNS format, in which the residue for each modulus is represented as a string in which the number of components taking a first value is equal to the residue. Corresponding components of the strings for different input entries are used to obtain a summation value, and the summation values are accumulated. Since the components of the string are not associated with weight values, the accumulation of the summation values can be performed without using a scaling accumulator.

### BRIEF DESCRIPTION OF THE FIGURES

Embodiments of the invention will now be illustrated for the sake of example only with reference to the following drawings, in which:

FIG. 1 shows a BC based DA system for computing an inner product of an input signal with a plurality of coefficients;

FIG. 2 shows a BC based DA-RNS system;

FIG. 3 shows a converter for converting an input signal into a digital RNS representation according to an embodiment of the present invention;

FIG. 4 shows zero-crossing based folding waveforms produced by circuits of the converter of FIG. 3 for moduli set [3,4,5];

FIG. 5 shows the zero-crossing based folding waveforms of FIG. 4 in the form of single-ended type waveforms and differential-ended type waveforms;

FIG. 6 shows a portion of the converter of FIG. 3 wherein the portion comprises comparators of the converter;

FIG. 7 shows waveforms of digital outputs from comparators of the converter for the zero-crossing based folding waveforms of FIG. 4;

FIG. 8 shows a table tabulating the digital outputs from the comparators of the converter for the zero-crossing based folding waveforms of FIG. 4;

FIG. 9 shows a portion of the converter of FIG. 3 wherein the portion comprises a first example encoder;

FIG. 10 shows a truth table tabulating digital outputs from the first example encoder shown in FIG. 9 for the zero-crossing based folding waveform outputs of FIG. 4;

FIG. 11 shows a variation of the converter of FIG. 3, wherein the variation comprises a second example encoder;

FIG. 12 shows a portion of the variation of the converter of FIG. 3;

FIG. 13 shows a truth table tabulating digital outputs from the second example encoder shown in FIG. 11 for the zero-crossing based folding waveform outputs of FIG. 4;

FIG. 14 shows a system for computing an inner product of an input signal with a plurality of coefficients according to an embodiment of the present invention, the system comprising a conversion unit, a formatting unit, a summation unit and an accumulating unit;

FIG. 15 shows a channel of the embodiment of FIG. 14 operating as a K=4 Thermometer Code (TC) based DA-RNS system;

FIG. 16 shows a BC based modular adder that may be used in the system of FIG. 14;

FIG. 17 shows an one-hot code (OHC) based modular adder that may be used in the system of FIG. 14;

FIG. 18 shows a channel of the system of FIG. 14 operating as a TC based DA-RNS system comprising an OHC based modular adder and configured to operate at 1BAAT;

FIG. 19 shows a channel of the system of FIG. 14 operating as a TC based DA-RNS system comprising an OHC based modular adder and configured to operate at 2BAAT;

FIG. 20 shows a first example TC based DA-RNS system comprising the converter of FIG. 3 and RNS based digital signal processing elements in the form of a plurality of FIR filter channels;

FIG. 21 shows a second example TC based DA-RNS system comprising the conversion unit in the form of either the converter of FIG. 3 or a Binary-to-RNS conversion circuit, and three channels of a FIR filter based on moduli set [5,7,8];

FIG. 22 shows the frequency response of the FIR filter of FIG. 21;

FIG. 23 shows an input waveform to the FIR filter with the frequency response shown in FIG. 22 and an output waveform of the FIR filter in response to the input waveform;

FIG. 24 shows a table tabulating entries of DALUTs of the FIR filter of FIG. 21;

FIG. 25 shows a table tabulating input signal entries to the FIR filter of FIG. 21 with the input signal entries in the RNS format whereby the input signal entries are from a portion of the input waveform of FIG. 23;

FIG. 26 shows a table tabulating residues of a subset of the input signal entries of FIG. 25 with the residues in the TC format;

FIG. 27 shows a table tabulating a sequence of bits sent to a first channel of the FIR filter of FIG. 21 and the corresponding outputs of the FIR filter for the first channel;

FIG. 28 shows a table tabulating a sequence of bits sent to a second channel of the FIR filter of FIG. 21 and the corresponding outputs of the FIR filter for the second channel;

FIG. 29 shows a table tabulating a sequence of bits sent to a third channel of the FIR filter of FIG. 21 and the corresponding outputs of the FIR filter for the third channel;

FIG. 30 shows a circuit arrangement of a DALUT of the FIR filter of FIG. 21 for the first channel;

FIG. 31 shows a timing diagram for the FIR filter of FIG. 21 for the first channel;

FIG. 32 shows a circuit arrangement of modular adders in each accumulator of the FIR filter of FIG. 21 for the second and third channels;

FIG. 33 shows a timing diagram for the FIR filter of FIG. 21 for the third channel;

FIGS. 34(a)-(d) show logic gate implementations for binary adders; and

FIG. 35 shows a table tabulating characteristics of two BC based modular adders and an OHC based modular adder.

### DETAILED DESCRIPTION OF THE EMBODIMENTS

### RNS-Based Analog-to-Digital Converter

### Analog-to-Digital Converter 300

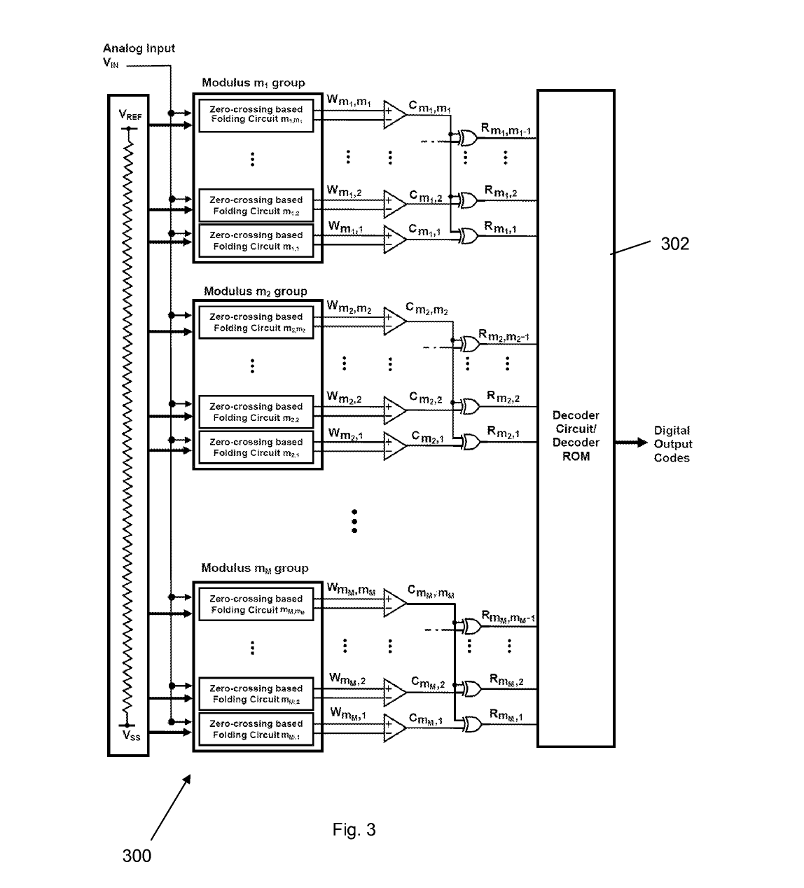

FIG. 3 illustrates an example architecture that may be used to implement an ADC 300 according to an embodiment of the present invention. ADC 300 is an RNS-based ADC. In other words, it converts an analog input signal into a digital RNS representation based on a plurality of relatively prime moduli.

As discussed above, the RNS relies on modular arithmetic principles, which allows an integer to be uniquely defined by its remainders (the residues or residue digits) when divided by a set of pair wise prime positive integers (these integers are also known as moduli and the set of these integers is known as a moduli set). As such, a feature of the RNS is that an integer within a large dynamic range (defined by the product of the moduli) can be uniquely represented by a set of residue digits that have much smaller values corresponding to the size of the moduli set used in the computation. For example, the residue digits from a moduli set [7,8,9] have values varying within the dynamic range of 0 to 6, 0 to 7 and 0 to 8 respectively and the maximum dynamic range provided by this moduli set [7,8,9] is [0,7×8×9=504) i.e. integers lying within the range of 0 to 503 can be uniquely represented by the residue digits from this moduli set [7,8,9]. An 8-bit integer in the range of 0 to 255 lies within this dynamic range and hence, can be uniquely and more than adequately represented by the residue digits from the moduli set [7,8,9]. For example, an integer 178 can be represented by the residue digits [symbol] 3,2,7 [symbol] _{7,8,9} using the moduli set [7,8,9].

The residue digits representing an integer follow a particular pattern as the integer value increases. In particular, as the integer value increases, the residue digit representing the integer increases as well and resets to 0 whenever the integer value reaches multiples of the modulus (including the modulus itself). For example, using the modulus m=7, the residue digits of an integer will follow a pattern of the form {0,1,2,3,4,5,6,0,1,2,3,4,5,6,0,1,2 , . . . } as the integer value increases linearly from 0 with an incremental value of 1. Hence, the digital output of the RNS-based ADC 300 should also follow a pattern. More specifically, the digital output of the ADC 300 should also reset itself repeatedly, in particular whenever the level of the analog input signal reaches multiples of the modulus used by the ADC 300.

As shown in FIG. 3, the ADC 300 comprises M groups of zero-crossing based folding circuits which operate in parallel where M is a positive non-zero integer greater than or equal to 2. The ADC 300 receives an analog input signal fed in parallel to the plurality of zero-crossing based folding circuits.

Each group of zero-crossing based folding circuits is configured for a different integer modulus mₙ, where n=1,2, . . . , M,M≧2 and may be referred to as a modulus mₙ group. Each integer modulus mₙ is relatively prime to the other integer moduli. In other words, other than 1, there is no common factor between the integer moduli. For example, the ADC 300 may comprise three moduli mₙ groups of zero-crossing based folding circuits for a M=3 moduli set [3,4,5] with m₁=3, m₂=4 and m₃=5 which are relatively prime to one another.

Each modulus mₙ group comprises mₙ parallel zero-crossing based folding circuits, each indexed m_{n,i} where i=1, . . . , mₙ. Each zero-crossing based folding circuit may be implemented with any type of circuit that is capable of performing the zero-crossing based foldings. Examples of such circuits are described in references [10], [11] and [12].

With an analog input signal whose level V_{IN} increases linearly, the mₙ zero-crossing based folding circuits in each modulus mₙ group produce mₙ zero-crossing based folding waveforms Wₘ_{ₙ}_{,1} to Wₘ_{ₙ}_{,m}_{ₙ}, each comprising multiple zero-crossings.

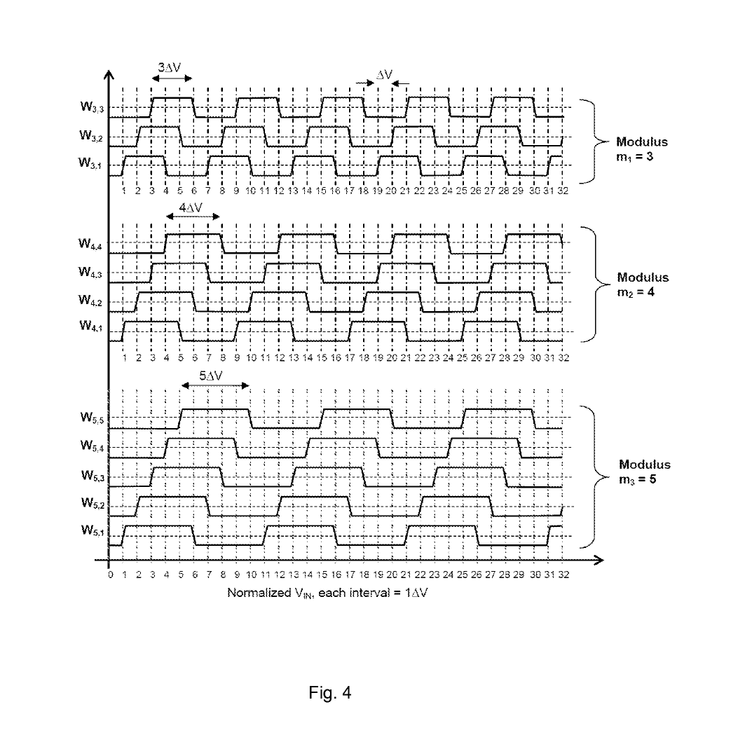

FIG. 4 illustrates the plurality of zero-crossing based folding waveforms produced by three modulus mₙ groups configured for the moduli set [3,4,5] comprising m₁=3, m₂=4 and m₃=5. In particular, FIG. 4 shows the phase differences between the zero-crossing based folding waveforms generated by each modulus group, as well as the phase differences between the zero-crossing folding waveforms across the three modulus groups. ΔV is the quantization level (or least significant bit size—LSB size) of the ADC 300 and represents the resolution of the ADC 300. ΔV may be expressed in volts, with practical values in the millivolt range or the microvolt range.

As shown in FIG. 4, the first zero-crossing based folding waveform Wₘ_{ₙ}_{,1} of each modulus mₙ group generated by the first zero-crossing folding circuit mₙ,1 has zero-crossings spaced apart by mₙΔV with the first zero-crossing occurring at 1ΔV. For example, referring to the modulus m₁=3 group illustrated in FIG. 4, it can be seen that the first waveform W_{3,1} in this group comprises zero-crossings at 1ΔV, 4ΔV, 7ΔV etc. Similarly, for the modulus m₂=4 group, the first waveform W_{4,1} comprises zero-crossings at 1ΔV, 5ΔV, 9ΔV etc.

The second zero-crossing based folding waveform Wₘ_{ₙ}_{,2} of each modulus mₙ group generated by the second zero-crossing based folding circuit mₙ,2 has zero-crossings spaced apart by mₙΔV with the first zero-crossing occurring at 2ΔV. Again, referring to the modulus m₁=3 group illustrated in FIG. 4, it can be seen that the second waveform W_{3,2} generated by the second zero-crossing based folding circuit comprises zero-crossings at 2ΔV, 5ΔV, 8ΔV etc. Similarly, for the modulus m₂=4 group, the second zero-crossing waveform W_{4,2} comprises zero-crossings at 2ΔV, 6ΔV, 10ΔV etc.

Similar patterns are also present in the zero-crossing based folding waveforms Wₘ_{ₙ}_{,i} generated by the remaining zero-crossing based folding circuits mₙ,i. In particular, the zero-crossing based folding waveforms for each modulus mₙ group are of the same general shape, but are phase shifted with respect to one another by a predetermined multiple of ΔV. More specifically, each of the plurality of zero-crossing based folding waveforms differs in phase from one other of the plurality of zero-crossing based folding waveforms by 1ΔV. In addition, each of the plurality of zero-crossing based folding waveforms produced by the modulus mₙ group has successive zero-crossings spaced apart by a multiple of the quantization level ΔV, whereby this multiple is equal to the modulus mₙ. The exact locations of the zero-crossings in each zero-crossing based folding waveform depend on the order of the circuit producing the waveform within the modulus mₙ group. All zero-crossings occur at cross-over points between two ΔV.

Furthermore, the mₙ zero-crossing based folding circuits for each modulus mₙ group have the same folding factor determined by the modulus mₙ. In other words, their zero-crossing based folding waveforms have the same number of zero-crossings or zero-crossing voltage transitions. Note that the folding factors must be able to provide the resolution and dynamic range required by the ADC 300. Thus, the total number of zero-crossings in the zero-crossing based folding waveforms depends on the dynamic range to be provided by the ADC 300. For example, if the ADC 300 is designed to be an 8-bit ADC, the number of zero-crossings in each zero-crossing based folding waveform may be either (2⁸−1)/mₙ or (2⁸)/mₙ, depending on the phase differences between the waveforms generated by the circuits mₙ,i within each modulus group mₙ. The zero-crossing based folding waveforms for each modulus group mₙ have to comprise a number of zero-crossings sufficient to represent the total number of LSBs required by the ADC 300.

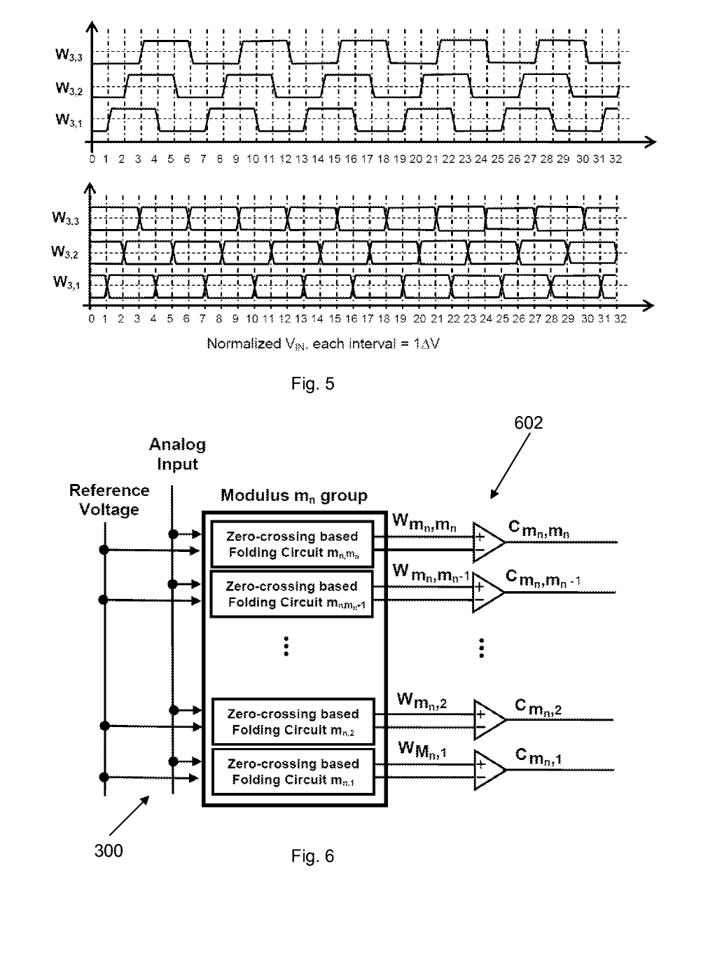

The zero-crossing based folding waveforms may be of the single-ended type or the differential-ended type which is more noise tolerant and common mode level insensitive. FIG. 5 illustrates the zero-crossing based folding waveforms in the form of single-ended type waveforms (top) and differential-ended type waveforms (bottom). It is preferable if the ADC 300 is implemented with the more practical and reliable differential-ended zero-crossing based folding waveforms. In this case, the zero-crossing based folding circuits may be based on differential amplifiers whose outputs are of differential-ended types. These outputs are then fed to differential input comparators which convert characteristics of the zero-crossing based folding waveforms to single-ended digital signals as will be discussed in more detail later.

Each modulus mₙ group of zero-crossing based folding circuits is configured to compare a level V_{IN} of the analog input signal at different points of the input signal against a set of reference voltages (or in other words, code transition voltage levels) to produce comparison outputs.

The zero-crossings of each zero-crossing based folding waveform are at a subset of the set of reference voltages. The reference voltages are multiples of the quantization level ΔV of the ADC 300, typically measured in volts. The actual amplitudes of the reference voltages may be in the millivolt or micro-volt range. Some of the reference voltages may be obtained from a reference ladder resistor network. To reduce the number of voltages needed from the reference ladder resistor network, additional voltages may be generated by an interpolation technique using the adjacent pair of zero-crossing based folding circuits required for producing zero-crossing based folding waveforms of appropriate folding factor. For example, referring to FIG. 4 (in particular, the modulus m₃=5 group), the initial reference voltages from the reference ladder resistor network may be used as the zero-crossings of the waveforms W_{5,1} and W_{5,5}, while the other zero-crossing based folding waveforms W_{5,2}, W_{5,3}, W_{5,4} may be generated by interpolating the zero-crossing based folding waveforms W_{5,1} and W_{5,5}. The voltages at the zero-crossings of the waveforms W_{5,2}, W_{5,3}, W_{5,4} form the remaining reference voltages against which the level V_{IN} of the analog input signal is compared.

The comparison outputs for each modulus mₙ group are based on the plurality of zero-crossing based folding waveforms produced by the modulus mₙ group. In particular, each comparison output is a point on a respective zero-crossing based folding waveform corresponding to the level V_{IN}. For each modulus mₙ group of zero-crossing based folding circuits, the comparison outputs are collectively output from the zero-crossing based folding circuits in the group and indicate a residue from a modulo operation on the input signal level V_{IN} based on the modulus mₙ. The value of the residue is related to the number of parallel zero-crossing based folding circuits and the folding factor in the modulus mₙ group.

A more specific example of how the zero-crossing based folding circuits operate is as follows. A level V_{IN} of the input signal at a point of the input signal is first compared against the reference voltages. This determines the location on the zero-crossing based folding waveforms the level V_{IN} corresponds to. The comparison outputs are the points of the waveforms at this location.

For example, in FIG. 4, the points on the zero-crossing based folding waveforms are at either logic low (logic 0) or logic high (logic 1). Each waveform in FIG. 4 is associated with a dotted horizontal line (or midpoint level) which indicates the transition between the two logic levels along the vertical axis. Except at the reference voltages, all points of the waveforms are unambiguously above or below their respective horizontal dotted lines. Referring to waveforms corresponding to the modulus m₁=3 group in FIG. 4, if a point of the input signal has a level between 3ΔV and 4ΔV, (after it is normalized) i.e. V_{IN} lies between 3ΔV and 4ΔV, then the comparison outputs are the points of the waveforms W_{3,1}, W_{3,2}, W_{3,3} at the location between 3ΔV and 4ΔV. As illustrated in FIG. 4, at this location, the waveforms W_{3,1}, W_{3,2} and W_{3,3} lie above their associated horizontal dotted lines. Therefore, the comparison outputs are 111 (i.e. a value of 3 when interpreted as a TC number). Similarly, referring to the modulus m₃=5 group, if the level V_{IN} lies between 2ΔV and 3ΔV, the comparison outputs produced by this modulus m₃=5 group of zero-crossing based folding circuits will be 00011 (i.e. a value of 2 when interpreted as a TC number). If the level V_{IN} lies between 14ΔV and 15ΔV, the comparison outputs produced by this modulus m₃=5 group of zero-crossing based folding circuits will be 01111 (i.e. a value of 4 when interpreted as a TC number and corresponding to |14|₅=4). Note that if a waveform is a differential-ended type waveform as shown in FIG. 5, the dotted horizontal line associated with it is obtained from the points of intersection between its pair of differential waves.

The ADC 300 further comprises a coding unit configured to transform the comparison outputs into the RNS representation. The coding unit, together with the zero-crossing based folding circuits, forms a RNS converter.

For each modulus mₙ, the coding unit comprises a plurality of comparators configured to convert the outputs of the plurality of zero-crossing based folding circuits (the comparison outputs) to a plurality of comparator bits with each comparator bit indicating the level of one of the plurality of waveforms (and in particular whether it has the characteristic of being above or below its associated horizontal dotted line).

FIG. 6 illustrates a portion of the ADC 300 in FIG. 3 for one modulus mₙ group with the comparators 602. The comparators 602 are in the form of mₙ differential input comparators that are used to detect and convert the outputs of the mₙ zero-crossing based folding waveforms into digital outputs or comparator bits Cₘ_{ₙ}_{,1}, to Cₘ_{ₙ}_{,m}_{ₙ}. Each comparator 602 is associated with a zero-crossing based folding circuit and each comparator bit Cₘ_{ₙ}_{,i} corresponds to the level of one of the zero-crossing based folding waveform (more specifically, waveform Wₘ_{ₙ}_{,i}).

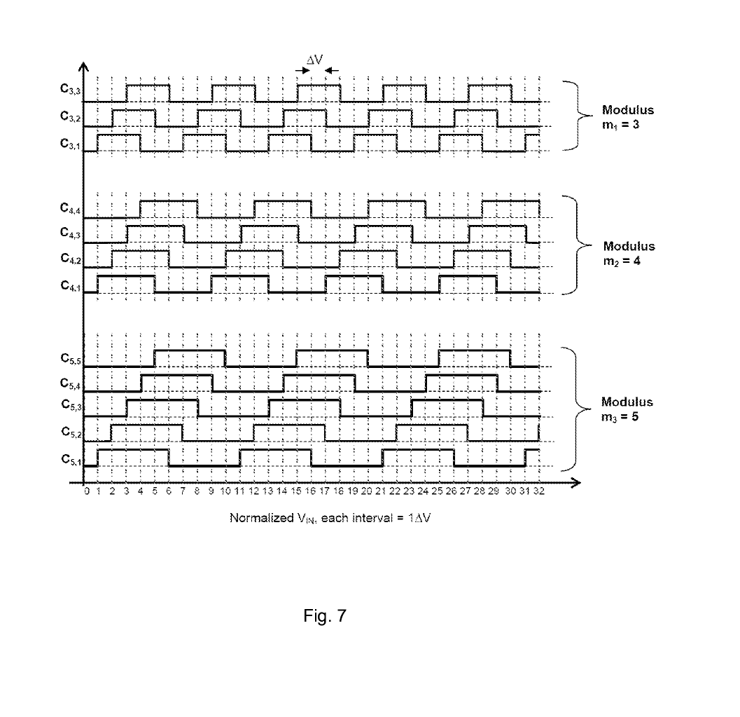

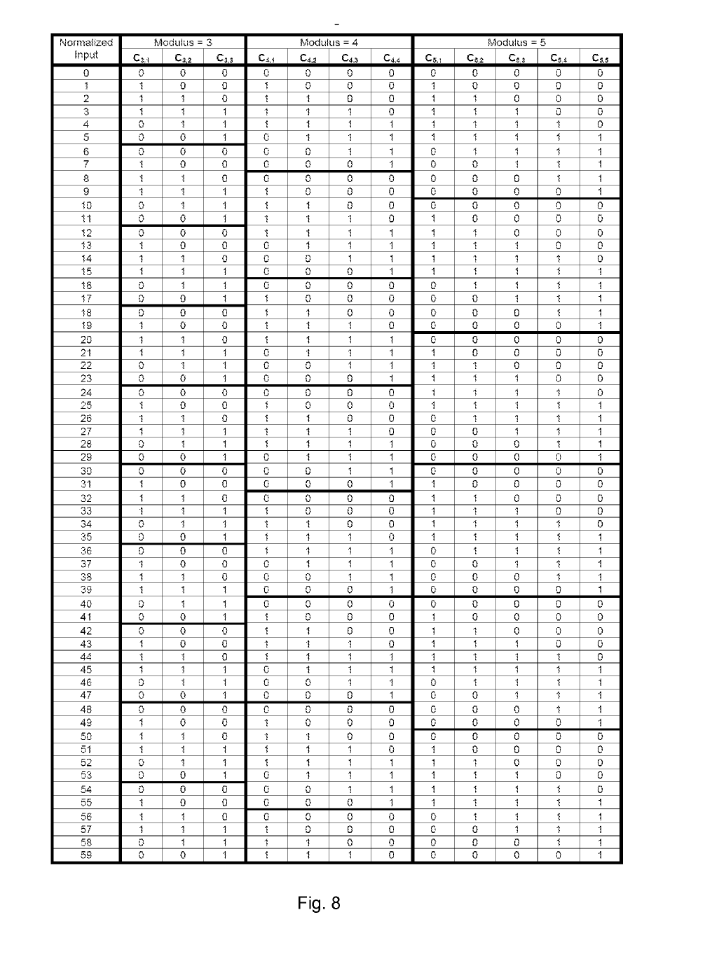

FIG. 7 shows waveforms of digital outputs from comparators in the coding unit of the ADC 300 when a moduli set [3,4,5] is used. FIG. 8 shows a table tabulating the digital outputs from the comparators with an input signal whose level linearly increases over the full dynamic range (3×4×5=60) associated with the moduli set [3,4,5]. “Normalized V_{IN}” refers to the analog input signal level (or voltage) V_{IN} normalized against ΔV (i.e. divided by ΔV), and rounded to the nearest lower integer. As can be seen from the table in FIG. 8, as the input signal level V_{IN} increases linearly, the comparators' digital outputs display a circular code pattern, wherein the comparator bits are shifted to the right in a circular manner, with this shift repeated at every 2-modulus interval.

The coding unit further comprises an encoder for each modulus mₙ whereby the encoder is configured to combine the plurality of comparator bits (from the comparators associated with the modulus mₙ group) to form a plurality of bits with a different format.

With a linearly increasing input signal level, the digital outputs from the encoder follow a pattern in which they are repeatedly reset to zero. More specifically, the digital outputs from the encoder are reset to zero every time the input signal level reaches the value, and multiples of the value of the modulus mₙ. In other words, these digital outputs encode the residue of the input signal level from a modulo operation based on the modulus mₙ. Thus, these digital outputs can be said to be in the RNS format i.e. the circular code pattern digital outputs (comparator bits) from the comparators associated with each modulus mₙ group are combined by the encoder to form digital outputs in the RNS format.

The encoder may comprise mₙ−1 circuits capable of performing the Exclusive OR (XOR) function. These circuits may comprise a plurality of XOR logic gates.

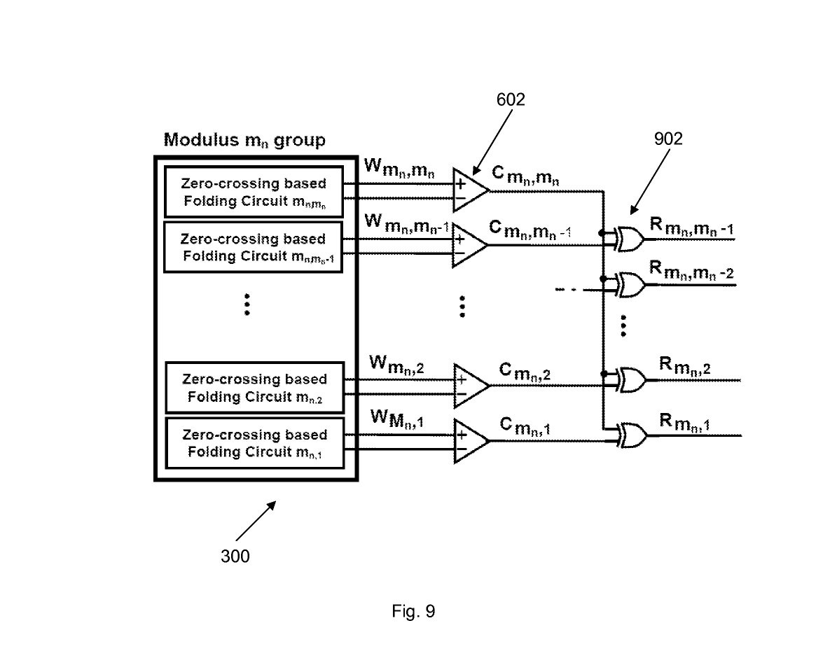

FIG. 9 illustrates a portion of the ADC 300 in FIG. 3 for one modulus mₙ group with the comparators 602 and a first example encoder (hereinafter, “Encoder #1”). Encoder #1 comprises a plurality of (mₙ−1) XOR logic gates 902 arranged to combine the modulus mₙ group's comparator bits Cₘ_{ₙ}_{,1} to C m_{ₙ}_{,m}_{ₙ} from the comparators 602 to form a plurality of bits Rₘ_{ₙ}_{,1} to Rₘ_{ₙ}_{,m}_{ₙ}₋₁ in the TC format.

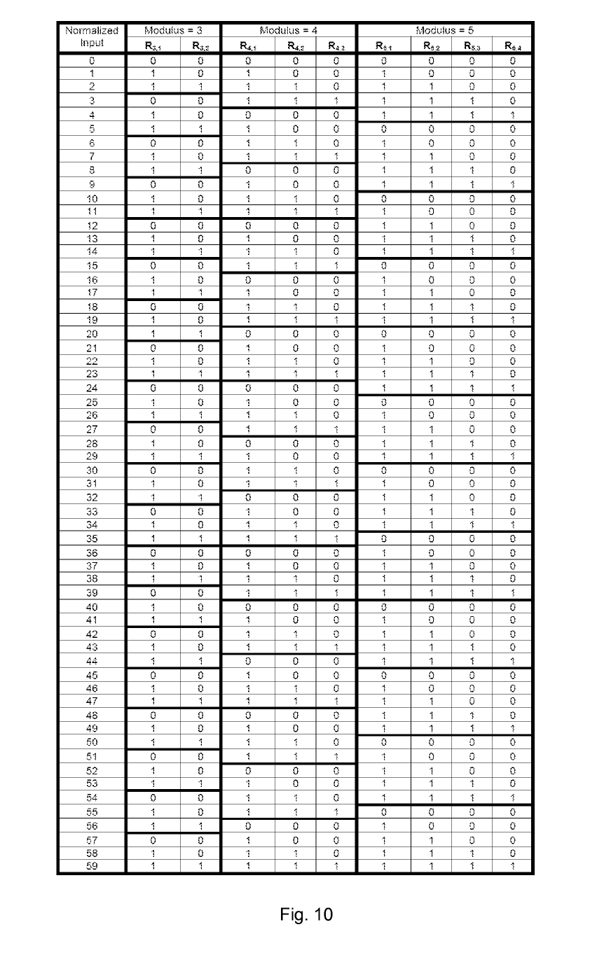

FIG. 10 shows a truth table tabulating digital outputs from Encoder #1. More specifically, the truth table tabulates residue digital output codes (with each code comprising bits Rₘ_{ₙ}_{,1} to Rₘ_{ₙ}_{,m}_{ₙ}₋₁) generated by the Encoder #1 at different input signal levels and for different modulus mₙ groups in a moduli set [3,4,5]. The number of bits ‘1’ in each code indicates the value of the residue of the corresponding normalized input signal level from a modulo operation based on the corresponding modulus. As shown in FIG. 10, as the normalized input signal level increases, the residue digital output code comprising the bits Rₘ_{ₙ}_{,1} to Rₘ_{ₙ}_{, m}_{ₙ}₋₁ repeatedly resets to 0. More specifically, the residue digital output code resets to 0 whenever the normalized input signal level reaches a multiple of mₙ. For example, referring to the modulus 5 group in FIG. 10, it can be seen that as the normalized input signal level increases, the output code {R_{5,1}, R_{5,2}, R_{5,3}, R_{5,4}} changes such that it displays a TC format that resets and repeats at levels 5, 10 and subsequent multiples of 5. Thus, it can be said that the residue digital output code follows a RNS pattern and is encoded in the TC format.

By combining the residue digital output codes from all the moduli groups, the corresponding input signal level within a dynamic range equal to the product of the moduli used by the ADC 300 can be uniquely determined. As shown in FIG. 3, the residue digital output codes from the XOR based encoder (Encoder #1) of all the moduli groups mₙ, n=1, . . . , M can be input into a decoder circuit 302. The decoder circuit 302 may be a logic based device capable of interpreting the residue digital output codes from the encoder to derive the input signal level V_{IN}. For example, the decoder circuit 302 may derive the input signal level V_{IN} (with a maximum dynamic range equal to the product of the non-redundant moduli) by decoding the residue digital output codes using the Chinese Remainder Theorem that can uniquely identify the input signal level V_{IN}. The decoder circuit 302 may also be a Read Only Memory (ROM) device comprising a truth table (decoding look-up table) relating the residue digital output codes to the input signal level V_{IN}. Alternatively, the residue digital output codes from the ADC 300 need not be decoded if they are to be input into digital computation circuits capable of performing signal processing algorithms directly in the RNS domain.

The RNS is capable of detecting and correcting bit errors when redundant moduli are used. Therefore, in one example, the ADC 300 uses redundant moduli. In other words, the ADC 300 uses a plurality of non-redundant moduli which are sufficient to provide the desired level of resolution of the input voltage (because their product is sufficiently high to encode the input voltage to this desired accuracy), and one or more additional moduli, which can be considered as redundant. These redundant moduli are also relatively prime with respect to each other and to the non-redundant moduli. The residues extracted by the ADC 300 for the redundant moduli can be compared against the residues extracted for the non-redundant moduli to check the accuracy of the residues obtained for the non-redundant moduli. Such ADCs are capable of performing self bit error detection and self bit error correction, and thus are more reliable. The ADC 300 may comprise a moduli mₙ group of zero-crossing based folding circuits and a coding unit for each redundant modulus so as to convert the analog input signal into additional residues based on the redundant modulus. These moduli mₙ groups of zero-crossing based folding circuits and coding units may be used with an appropriate decoder or computation circuit that is capable of performing the error detection and correction functions. Reference [14] is a reference on the error detection and correction properties of the RNS.

Because of the modular nature of the circuit arrangements in the ADC 300 as well as the mathematical properties of the RNS, it is possible to independently enable and disable each moduli mₙ group of zero-crossing based folding circuits and its associated coding unit. In one example, a control unit comprising a control circuit is configured to enable and disable the zero-crossing based folding circuits and associated coding units for a subset of the plurality of moduli used by the ADC 300. Disabling the zero-crossing based folding circuits and coding units for a subset of the plurality of moduli does not affect the general operation of the ADC 300, except that it lowers the resolution and dynamic range provided by the ADC 300. Therefore, the number of moduli used can be reduced if a lower resolution and a smaller dynamic range are acceptable. For instance, a moduli set [7,8,9] provides a maximum dynamic range of 504 and instead of using this moduli set, it is possible to remove the modulus 7 and use a new moduli set [8,9] when a smaller dynamic range of 9×8=72 is acceptable.

### Variation of the ADC 300-ADC 300′

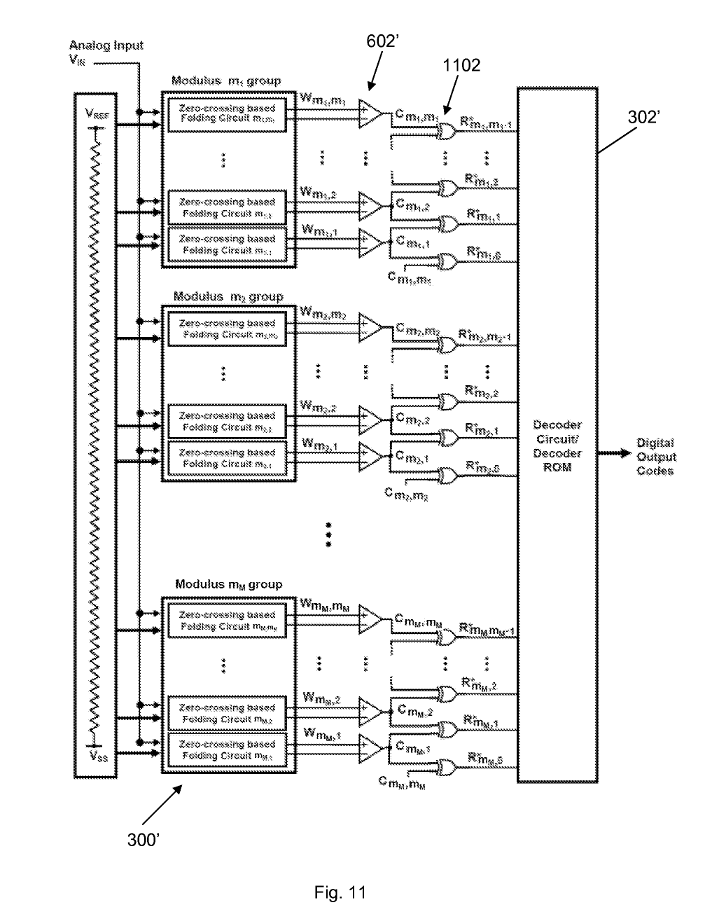

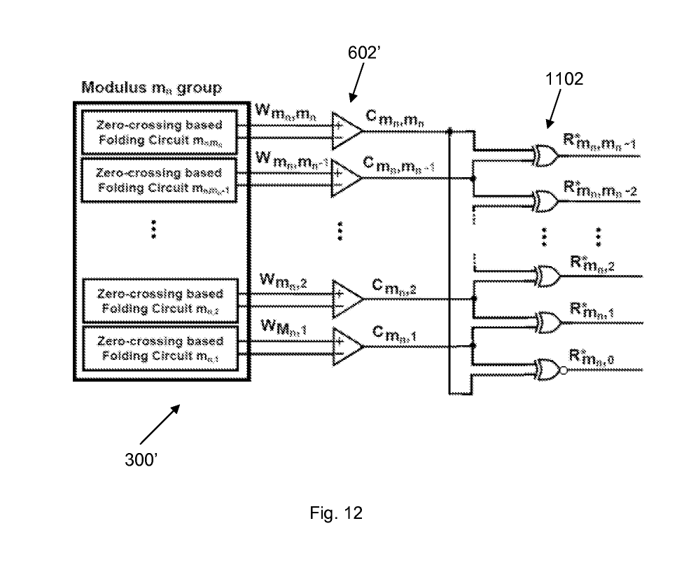

FIG. 11 shows an ADC 300′ which is a variation of the ADC 300 and FIG. 12 shows a portion of the ADC 300′. The ADC 300′ is similar to the ADC 300 and thus, the same parts will have the same reference numerals, with addition of prime.

The ADC 300′ comprises a second example encoder (hereinafter, “Encoder #2”) instead of Encoder #1 in FIGS. 3 and 9. Only the encoder for a single modulus mₙ group is shown in FIG. 12. Encoder #2 comprises a plurality of (mₙ−1) XOR logic gates 1102 arranged to combine the modulus mₙ group's comparator bits Cₘ_{ₙ}_{,1} to Cₘ_{ₙ}_{, m}_{ₙ} from the comparators 602′ to form a plurality of bits R*ₘ_{ₙ}_{,0} to R*ₘ_{ₙ}_{, m}_{ₙ}₋₁ in the one-hot code format, where R*ₘ_{ₙ}_{,0}=1 represents the value of zero.

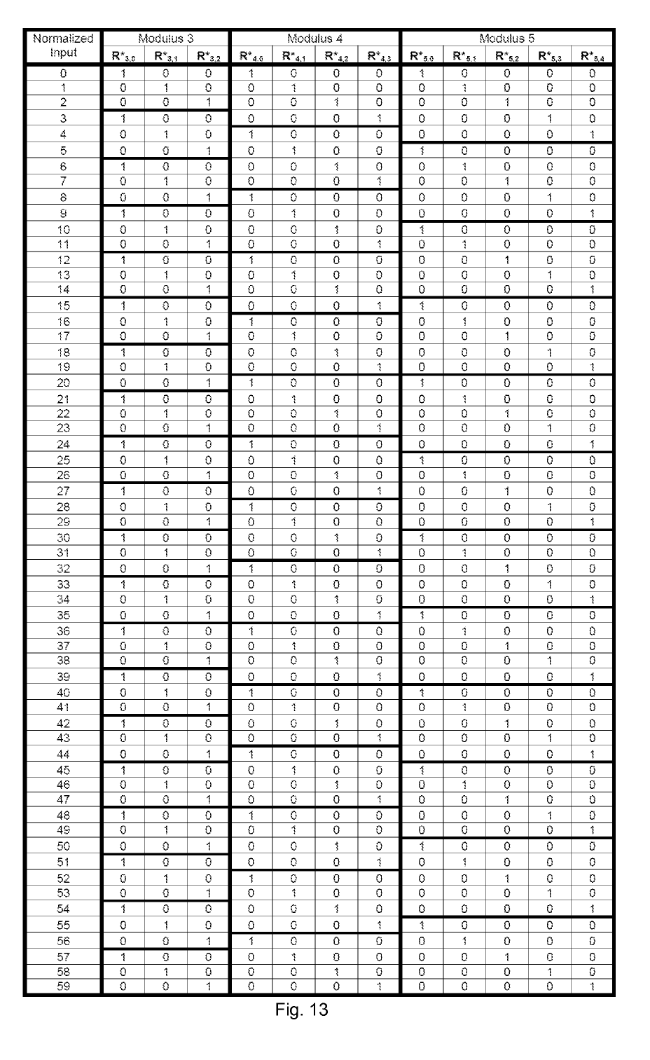

FIG. 13 shows a truth table tabulating digital outputs from Encoder #2. More specifically, the truth table tabulates residue digital output codes (with each code comprising bits R*ₘ_{ₙ}_{,0} to R*ₘ_{ₙ}_{, m}_{ₙ}₋₁) generated by the Encoder #2 at different input signal levels and for different modulus mₙ groups in a moduli set [3,4,5]. The position of the bit ‘1’ in each code indicates the value of the residue of the corresponding normalized input signal level from a modulo operation based on the corresponding modulus. As shown in FIG. 13, as the normalized input signal level increases, the residue digital output code comprising the bits R*ₘ_{ₙ}_{,0} to R*ₘ_{ₙ}_{, m}_{ₙ}₋₁ repeatedly resets to the value of zero (i.e. R*ₘ_{ₙ}_{,0}=1). More specifically, the residue digital output code resets to zero whenever the normalized input signal level reaches a multiple of mₙ. Thus, it can be said that the residue digital output code follows a RNS pattern and is encoded in the one-hot code format.

Similar to the Encoder #1, by using a combination of the residue digital output codes generated by Encoder #2 of all the moduli group, it is possible to uniquely determine the corresponding input signal level within a dynamic range equal to the product of the moduli used by the ADC 300′. As shown in FIG. 11, the residue digital output codes from the XOR based encoder (Encoder #2) of all the moduli groups mₙ, n=1, . . . , N can also be input into a decoder circuit 302′. Preferably, the decoder circuit 302′ used with the ADC 300′ is a ROM decoder as the output of Encoder #2 is in the one-hot code format and hence, it is simpler to use the decoding look-up table for deriving the input signal level V_{IN}.

Similar to the ADC 300, the ADC 300′ may also use redundant moduli. Furthermore, each moduli mₙ group of zero-crossing based folding circuits and its associated coding unit in the ADC 300′ may also be independently enabled and disabled.

### Advantages of the ADC 300 and its Variation 300′

The ADC 300 or its variation 300′ is a highly efficient ADC with several advantages over existing ADCs. The following describes some of the advantages of the ADC 300 and its variation 300′.

As compared to the Folding ADC and the Flash ADC, the ADC 300 or 300′ uses a smaller number of parallel paths to achieve a same resolution. The ADC 300 or 300′ uses a zero-crossing based folding circuit together with one comparator for every parallel path and compared to the commonly used parallel based Flash ADC, a much smaller number of comparators is required for the ADC 300 or 300′ to provide a particular dynamic range. For example, an 8-bit ADC in the form of the ADC 300 or 300′ using a [7,8,9] moduli set can be more than adequately implemented by using 7+8+9=24 comparators i.e. 24 parallel paths whereas an 8-bit Flash ADC requires 2⁸−1=255 parallel paths and an 8-bit Folding ADC requires 2(2⁴−1)=30 parallel paths. The difference in the number of parallel paths required by a Folding ADC, a Flash ADC and ADC 300 or 300′ becomes even more pronounced when higher resolutions are required. For example, to implement a 10-bit ADC, the Flash ADC will need 1023 comparators, the Folding ADC will need 2(25−1)=62 comparators whereas the ADC 300 or 300′ will only require 9+11+13=33 comparators when using the [9,11,13] moduli set. This great reduction in the number of comparators and parallel paths required by the ADC 300 or 300′ is possible as the operations of the ADC 300 or 300′ are based on the theory of modular arithmetic using the RNS. Furthermore, despite the reduction in the number of parallel paths, the speed performance of the ADC 300 or 300′ is not inferior to that of the Folding ADC or the Flash ADC.

In addition, the RNS modular arithmetic also provides the ADC 300 or 300′ features of built-in bit error detection and bit error correction capability of its output bits. This is possible because of the error detection properties of the Redundant Residue Number System (RRNS). In particular, the ADC 300 or 300′ is capable of detecting and correcting errors in its output when redundant moduli are used. Extra parallel circuitry such as additional zero-crossing based folding circuits may be included for these redundant moduli. Thus, the ADC 300 or 300′ is capable of achieving a more reliable and accurate operation.

Furthermore, the ADC 300 or 300′ may comprise a control unit that enables and disables the zero-crossing based folding circuits and coding units for a subset of the plurality of moduli used. This allows an adaptive variation in the conversion resolution of the ADC 300 or 300′ to suit the need of the system operation that the ADC 300 or 300′ is used in, thereby allowing power management and reducing the overall power consumption of the system. In particular, when a lower resolution and a smaller dynamic range are acceptable, the zero-crossing based folding circuits and coding units for a subset of the plurality of moduli used by the ADC 300 or 300′ may be disabled. Although the device's resolution level is sacrificed, a lower operation power can be achieved and this is beneficial especially for devices such as a battery operating mobile device. The zero-crossing based folding circuits and coding units may be enabled again when a higher resolution and a higher dynamic range are required.

While it is true that modular arithmetic has been applied in analog to digital conversion (see reference [13]), there are distinct differences between Pace's proposal and the ADC 300 or 300′.

The first difference is as follows. Pace's proposal requires the use of analog folding circuits with high linearity characteristics and accurate reference voltages for proper operation. Furthermore, the folding waveforms used for Pace's proposal are of a triangular shape that needs to bend sharply at the peaks of the waveforms while maintaining symmetry along the linear slopes of the waveforms. In contrast, the ADC 300 or 300′ only requires the zero-crossing based folding circuits to operate with accurate reference voltages to achieve the foldings. In particular, each of the zero-crossing based folding circuits only needs to determine whether the analog input signal level has crossed the reference voltages. Hence, the zero-crossing based folding circuits of ADC 300 or 300′ operate more like digital circuits where circuit linearity is irrelevant. This provides a significant advantage over Pace's proposal in terms of implementation practicality as the ADC 300 or 300′ may be implemented with a lower circuit complexity.

The second difference is in the output format of Pace's proposal and the ADC 300 or 300′. Pace's proposal outputs a digital code in a format that he refers to as Symmetrical Number System (SNS) in his publication [15]. Due to the ambiguity caused by the symmetrical triangular folding waveforms used in Pace's proposal, the SNS format has the disadvantage of requiring a complicated decoding process and/or additional steps to convert the outputs to the RNS format in order to apply the modular arithmetic algorithm for further processing. In contrast, the ADC 300 or 300′ outputs digital codes inherently in the RNS format. Note that the RNS format is technically based on a saw-tooth waveform while the SNS format is based on a triangular waveform, although in the ADC 300, no saw-tooth waveform is actually needed. The encoding of the digital codes output by the ADC 300 or 300′ with the RNS format is advantageous as efficient execution of signal processing algorithms may be performed on these digital codes directly based on modular arithmetic principles. Furthermore, encoding the digital codes output by the ADC 300 or 300′ with the RNS format allows unique identification of the corresponding analog input signal level.

Computation System for Computing an Inner Product of an Input Signal with a Plurality of Coefficients

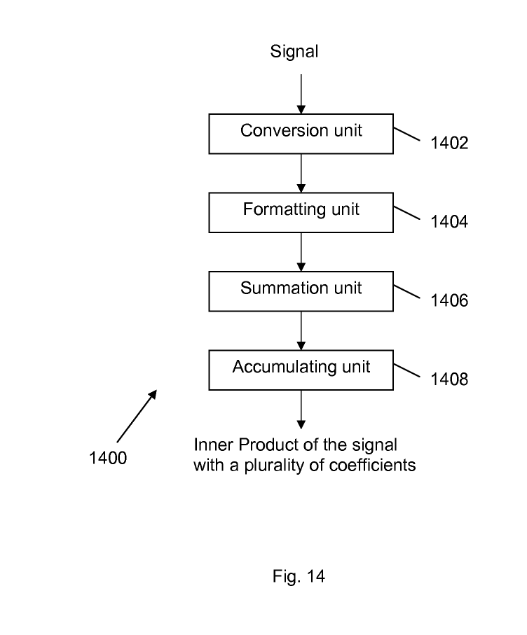

Referring to FIG. 14, a system 1400 for computing an inner product of an input signal with a plurality of coefficients Aₖ according to an embodiment of the present invention is shown. It comprises a conversion unit 1402 (optionally in the form of an ADC converter), a formatting unit 1404, a summation unit 1406 and an accumulating unit 1408. These units will now be described in more detail.

### Conversion Unit 1402

The conversion unit 1402 is configured to output the input signal in a representation comprising a plurality of input signal entries whereby the representation is in a bit-parallel format. For example, the input signal may be in the form of a K-component vector \vec{x}ₖ=[x₀,x₁, . . . , x_{K-1}], where x₀,x₁, . . . , x_{K-1} are the input signal entries. Each input signal entry xₖ indicates a characteristic of the input signal (for example, a level or magnitude of the input signal) at a point of the input signal (which may be a point in time if the input signal is a time signal).

If the input signal is an analog signal, the conversion unit 1402 is in the form of an ADC converter.

In one example, the conversion unit 1402 is in the form of an ADC 300 of the kind described above in relation to FIG. 3 (without the decoder circuit 302). The ADC 300 converts the input signal, one signal entry at a time, into the RNS representation. As mentioned above, the ADC 300 may use redundant moduli and in this case, the system 1400 uses the redundant moduli as well.

However, note that the conversion unit 1402 of the DA-RNS system 1400 can also be in the form of other types of ADC. For example, the conversion unit 1402 may be in the form of an ADC that outputs data in the BC format and in this case, the BC formatted data may be converted to a format required by the summation and accumulating units 1406, 1408 before they are fed to the formatting unit 1404.

In any case, the conversion unit 1402 converts the input signal into a digital representation based on the residue number system (RNS) which uses a plurality of M relatively prime moduli, specifically a moduli set mᵢ=[m₁,m₂, . . . , m_{M}]. Each input signal entry is represented as a plurality of residues, corresponding to respective moduli of the plurality of moduli used by the system 1400. More specifically, each residue corresponds to an output from a modulo operation on the input signal entry based on its respective modulus.

Each residue is encoded as a binary string having a plurality of bits or in other words, components (at least) equal to the modulus minus one. The string has a number of bits taking a first value (say “1”) equal to the residue. Thus, the plurality of bits encoding each residue have equal weights. Any format may be used to encode the residues as long as the number of bits in the binary string taking the first value is equal to the residue.

In a more specific example, each residue is encoded in a thermometer code format as discussed below. Such a residue may be referred to as a thermometer code residue (TCR).

Thermometer code (TC) format refers to an encoding format which comprises a plurality of binary bits taking either a value of ‘0’ or ‘1’. The number of binary bits taking the value of ‘1’ is equal to the value of the datum the format encodes. For example, using the TC format, an integer with a value of 5 can be represented using a plurality of bits with the bit pattern {11111} comprising 5 bits ‘1’ (i.e. 5 bits with the value of ‘1’). Binary bits with a value of ‘0’ (i.e. bits ‘0’) may also be added to explicitly indicate the dynamic range (DR) associated with the datum. For example, an integer with a value of 5 and with a dynamic range of 10 may be represented by a plurality of bits with the bit pattern {0000011111}.

Mathematically, a TC encoded number system is a unary numeral system which is equivalent to a base-1 bit system when the symbol used is the binary bit. It is also common to describe it as a no place-value number system, since the positions of its bits ‘1’ in the bit pattern are not important. In other words, the bits representing a datum in the TC format have equal weights and the TC format can be referred to as an equal place-value number system.

In the output of the conversion unit 1402, each residue may be expressed in terms of its plurality of bits tₖₙ, according to Equation (19). In Equation (19), |xₖ|ₘ_{ᵢ} is the residue of the k^{th} input signal entry corresponding to the modulus mᵢ. tₖₙ are binary bits taking either a value of ‘0’ or ‘1’, with each bit tₖₙ being at the n^{th} bit position and having a equal weight 2⁰, i.e. 1.

$${\vert {x}_{k} \vert}_{{m}_{i}} = {\sum }_{n = 1}^{{m}_{i} - 1} {t}_{{k}_{n}} {2}^{0} {t}_{kn} ∈ [ 0 , 1 ] \qquad ( 19 )$$

Some features associated with TC based modular arithmetic are as follows. Modular addition of two TCRs can be done by first concatenating the bits encoding the TCRs. Then, the modulo operation can be done by checking a single bit of the output after removing the trailing ‘0’ of the concatenated bits as described below.

Consider an example with two TCRs, r₁ and r₂, each corresponding to an integer modulus m with decimal value of n. Let r₁ consisting of (n−1) bits ‘1’ and r₂ consisting of (n−3) bits ‘1’ be represented as follows, where each tₓ corresponds to a binary bit of value ‘1’ situated at bit position x in the r₁ and r₂ TC data.

r₁=0tₙ₋₁tₙ₋₂tₙ₋₃ . . . t₃t₂t₁

r₂=000tₙ₋₃tₙ₋₄tₙ₋₅ . . . t₃t₂t₁

The modulo addition of r₁ and r₂ comprises first concatenating r₁ with r̅₂, where r̅₂ corresponds to a r₂ that has undergone a bitwise logical left shift (which may be performed through cross-wired connection in practice) such that all the bits ‘1’ in r̅₂ occupy the left most positions in its TCR data format. The resulting datum is a 2n bits intermediate sum of the two thermometer residues with (2n−4) bits ‘1’ as follows.

$${r}_{1} + {r}_{2} ≡ {r}_{1} {\overline{r}}_{2} = ( 0 {t}_{n - 1} {t}_{n - 2} {t}_{n - 3} … {t}_{3} {t}_{2} {t}_{1} ) ( {t}_{n - 3} {t}_{n - 4} {t}_{n - 5} … {t}_{3} {t}_{2} {t}_{1} 000 ) = 0 {t}_{2 n - 4} {t}_{2 n - 5} {t}_{2 n - 6} … {t}_{3} {t}_{2} {t}_{1} 000$$

This intermediate sum is then logically shifted to the right by 3 bits to form a 2n-bit length TCR normalized to its rightmost bit position as follows:

r₁ r̅₂>>3=0000t₂ₙ₋₄t₂ₙ₋₅t₂ₙ₋₆ . . . t₃t₂t₁

Performing the modulo operation of this intermediate sum in the third step is done in hardware by testing the bit value of the normalized intermediate sum's n^{th} bit (which corresponds to the value of the modulus used for these TCRs). Based on this n^{th} bit value, a circuit (e.g. a multiplexers based circuit) selects the lower n bits if the n^{th} bit has a bit value of ‘0’ or the upper n bits if the n^{th} bit value is equal to ‘1’.

Modular subtraction operation for TCRs can also be similarly performed by concatenating the minuend with the additive inverse of the subtrahend, where the additive inverse of a TCR is obtained by taking the one's (1's) complement of its plurality of bits. With TCR based modulo operation, there is also no ambiguity in taking the additive inverse of a value ‘0’. This is because the one's complement of the plurality of bits in the TCR of the value ‘0’ is equal to the TCR of the modulus which reverts to the TCR of the value ‘0’ after the modulo operation.

### Formatting Unit 1404

System 1400 further comprises a formatting unit 1404. The formatting unit 1404 is configured to convert the output of the conversion unit 1402 in the bit-parallel format to the bit-serial format. The formatting unit 1404 is further configured to send the bit-serial formatted data to the summation unit 1406.

### Summation Unit 1406

System 1400 employs the DA technique and the RNS as mentioned above. Thus, it may be referred to as a DA-RNS system. A system 1400 whose summation unit 1406 receives input signal entries with residues encoded in the TC format may be referred to as a TC based DA-RNS system.

It is preferable if the TC based DA-RNS system uses more moduli with small values rather than a few moduli with medium values. For example, it is preferable to use a [5,7,8,9] moduli set rather than a [11,13,15] moduli set to cover a range equivalent to the range of a 11-bit BC system. This allows a more efficient use of the TC format with the RNS.

The equations governing the TC based DA-RNS system are similar to those governing the BC based DA-RNS system as mentioned above. However, instead of the BC's bit expression as shown in Equation (4), the TCR's bit expression as shown in Equation (19) is used. In other words,

$${x}_{k} = {\sum }_{n = 0}^{N - 1} {b}_{kn} {2}^{n} ⇔ {\vert {x}_{k} \vert}_{{m}_{i}} = {\sum }_{n = 1}^{{m}_{i} - 1} {t}_{kn} {2}^{0} \qquad ( 20 )$$

The residue expression (corresponding to Equation (18)) for the TC based DA-RNS system can then be obtained by replacing the symbols used in Equation (18) with the TCR equivalents, namely, the number of bits for TCR is equal to mᵢ−1, and all bits are of equal weight, 2⁰=1. This residue expression is shown in Equation (21) where yᵢ is the inner product for the modulus mᵢ (more specifically, yᵢ is the residue from a modulo operation on the inner product of the input signal with the plurality of coefficients Aₖ, whereby the modulo operation is based on the modulus mᵢ). The inner product of the input signal with the plurality of coefficients Aₖ may be derived by combining all the inner products obtained for the plurality of moduli (for example, a binary representation of the inner product may be obtained by performing a reverse conversion using the Chinese Remainder Theorem). In other words, the inner product of the input signal with the plurality of coefficients Aₖ is a combination of the inner products obtained for the plurality of moduli after performing a reverse conversion.

$$\begin{matrix}{y}_{i} = \vert {\sum }_{n = 1}^{{m}_{i} - 1} \vert {f}_{{m}_{i}} ( {A}_{k} , {t}_{kn} ) {\vert {2}^{0} \vert}_{{m}_{i}} {{\vert}_{{m}_{i}} \vert}_{{m}_{i}} \\ = {\vert {\sum }_{n = 1}^{{m}_{i} - 1} {f}_{{m}_{i}} ( {A}_{k} , {t}_{kn} ) \vert}_{{m}_{i}} since {\vert {2}^{0} \vert}_{{m}_{i}} = 1\end{matrix} \qquad ( 21 )$$

Based on Equation (17), the expression of fₘ_{ᵢ}(Aₖ,tₖₙ) may be written as:

$${f}_{{m}_{i}} ( {A}_{k} , {t}_{kn} ) = {\vert {\sum }_{k = 0}^{K - 1} {A}_{k} {t}_{kn} \vert}_{{m}_{i}} \qquad ( 22 )$$

The values of fₘ_{ᵢ}(Aₖ,tₖₙ) from Equation (22) may be referred to as summation values. The summation unit 1406 of system 1400 is configured in a set of M channels, and each channel is configured to provide these summation values for the corresponding modulus value. In other words, the summation unit 1406 is configured to provide, for each modulus mᵢ, summation values arising from dot products

$${\sum }_{k = 0}^{K - 1} {A}_{k} {t}_{kn}$$

between the bits tₖₙ, of the residues corresponding to the modulus mᵢ and the plurality of coefficients Aₖ, and modulo operations |•|ₘ_{ᵢ} on the dot products

$${\sum }_{k = 0}^{K - 1} {A}_{k} {t}_{kn}$$

based on the modulus mᵢ.

As shown in Equation (22), the DA technique is used. In particular, for each modulus, the dot product each summation value arises from is performed for a bit position n whereby the dot product is between the bits tₖₙ at the bit position n (in other words, the bits t₀ₙ,t₁ₙ . . . , t_{(K-1)n}) of the residues corresponding to the modulus mᵢ and the plurality of coefficients Aₖ. In other words, the summation values represent the sum of the coefficients Aₖ over those of the set of corresponding bits which take the value 1.

In one example, the summation unit 1406 comprises a memory which in turn comprises a plurality of Look-Up-Tables (LUTs) (also referred to as DALUTs) with memory addresses addressable using the bits of the input signal entries. Each channel of the summation unit 1406 corresponding to each modulus mᵢ comprises a DALUT. For each modulus mᵢ, the DALUT stores the values of fₘ_{ᵢ}(Aₖ,tₖₙ) (i.e. summation values) arising from all possible combinations of the bits tₖₙ of the residues corresponding to the modulus. In the practical implementation of the TC based DA-RNS system, the plurality of DALUTs corresponding to different moduli may be implemented in a single IC but they operate independently of one another. Furthermore, the summation values stored in the DALUTs may be encoded in a BC format.

For each modulus mᵢ, the summation unit 1406 is configured to provide the summation values for successive values of n, by successively addressing the DALUT using an address string of length K, generated from the K bits tₖₙ at the bit position n of the residues corresponding to the modulus mᵢ i.e. |x₀|ₘ_{ᵢ},|x₁|ₘ_{ᵢ}, . . . |x_{K-1}|ₘ_{ᵢ}. This addressing is performed until the summation values for all the bit positions n are provided. The addressing may be done in an increasing order of n, for example, from n=1 until n=mᵢ−1 and may also be done in a plurality of clock cycles whereby in each clock cycle, the summation values for one bit position n are provided.

### Accumulating Unit 1408

The accumulating unit 1408 is configured to execute the summation and modulo operation in the residue expression

$${y}_{i} = {\vert {\sum }_{n = 1}^{{m}_{i} - 1} {f}_{{m}_{i}} ( {A}_{k} , {t}_{kn} ) \vert}_{{m}_{i}}$$

as shown in Equation (21) for each modulus. In other words, it is configured to obtain an inner product yᵢ for each modulus mᵢ by cumulatively adding the summation values provided for the modulus mᵢ and performing a modulo operation on the cumulative sum based on the modulus mᵢ.

As shown in Equation (18), when the BC format is used to encode the residues of the input signal entries, it is necessary to scale fₘ_{ᵢ}(Aₖ,bₖₙ) with a 2ⁿ scaling factor before performing the summation for the residue expression. On the other hand, as shown in Equation (21), there is no need for this scaling operation when the TC format is used to encode the residues of the input signal entries. In other words, the accumulating unit 1408 of the TC based DA-RNS system is configured to perform the above-mentioned summation and modulo operation on the summation independent of the weights of the bits tₖₙ. Hence, there is no longer the complication associated with the BC based DA-RNS system's accumulation process described above.

If a modulo operation is performed only after the summation of the summation values for all the bit positions i.e. only after

$${\sum }_{n = 1}^{{m}_{i} - 1} {f}_{{m}_{i}} ( {A}_{k} , {t}_{kn} )$$

is completed, the accumulating unit 1408 may overflow. Therefore, it is preferable to expand Equation (21) using the algebra of residue as shown below and execute modulo addition operations successively as the summation values are obtained. This can be more clearly illustrated using the example below in which a modulo operation is performed after every addition.

$$\begin{matrix}{y}_{i} = {\vert {\sum }_{n = 1}^{{m}_{i} - 1} {f}_{{m}_{i}} ( {A}_{k} , {t}_{kn} ) \vert}_{{m}_{i}} \\ = {\vert {f}_{{m}_{i}} ( {A}_{k} , {t}_{k 1} ) + {f}_{{m}_{i}} ( {A}_{k} , {t}_{k 2} ) + {f}_{{m}_{i}} ( {A}_{k} , {t}_{k 3} ) … + {f}_{{m}_{i}} ( {A}_{k} , {t}_{k ( {m}_{i} - 1 )} ) \vert}_{{m}_{i}} \\ = \vert \vert {\vert {f}_{{m}_{i}} ( {A}_{k} , {t}_{k 1} ) + {f}_{{m}_{i}} ( {A}_{k} , {t}_{k 2} ) \vert}_{{m}_{i}} + {f}_{{m}_{i}} ( {A}_{k} , {t}_{k 3} ) … + \\ {f}_{{m}_{i}} ( {A}_{k} , {t}_{k ( {m}_{i} - 1 )} ) {\vert}_{{m}_{i}} {\vert}_{{m}_{i}} \\ = \vert \vert … \vert \vert {f}_{{m}_{i}} ( {A}_{k} , {t}_{k 1} ) + {f}_{{m}_{i}} ( {A}_{k} , {t}_{k 2} ) {{\vert}_{{m}_{i}} + {f}_{{m}_{i}} ( {A}_{k} , {t}_{k 3} ) \vert}_{{m}_{i}} … + \\ {{ {f}_{{m}_{i}} ( {A}_{k} , {t}_{k ( {m}_{i} - 1 )} ) \vert}_{{m}_{i}} \vert}_{{m}_{i}}\end{matrix}$$

In other words, it is preferable to configure the accumulating unit 1408 to obtain the inner product yᵢ for each modulus by (a) performing a summation of a first subset of the summation values (e.g. fₘ_{ᵢ}(Aₖ,tₖ₁),fₘ_{ᵢ}(Aₖ,tₖ₂)) provided for the modulus mᵢ to obtain a first subset-output (e.g. fₘ_{ᵢ}(Aₖ,tₖ₁)+fₘ_{ᵢ}(Aₖ,tₖ₂)) and a modulo operation on the first subset-output to obtain a first partial-output (e.g. |fₘ_{ᵢ}(Aₖ, tₖ₁)+fₘ_{ᵢ}(Aₖ,tₖ₂)|ₘ_{ᵢ}), and (b) successively obtaining further partial-outputs in a plurality of iterations by performing the following steps in each iteration: (i) adding to a most recently obtained partial-output (e.g. |fₘ_{ᵢ}(Aₖ,tₖ₁)+fₘ_{ᵢ}(Aₖ, tₖ₂)|ₘ_{ᵢ}) a subsequent subset of the summation values (e.g. fₘ_{ᵢ}(Aₖ,tₖ₃)) provided for the modulus to obtain a subsequent subset-output (e.g. |fₘ_{ᵢ}(Aₖ,tₖ₁)+fₘ_{ᵢ}(Aₖ, tₖ₂)|ₘ_{ᵢ}+fₘ_{ᵢ}(Aₖ,tₖ₃)), and (ii) performing a modulo operation on the subsequent subset-output to obtain a further partial-output (e.g. ∥fₘ_{ᵢ}(Aₖ,tₖ₁)+fₘ_{ᵢ}(Aₖ, tₖ₂)|ₘ_{ᵢ}+fₘ_{ᵢ}(Aₖ,tₖ₃)|ₘ_{ᵢ}). The further partial-output obtained in the last iteration is the inner product for the modulus.

In one example, the accumulating unit 1408 comprises a plurality of channels with each channel corresponding to one modulus mᵢ. The accumulating unit 1408 further comprises a plurality of accumulators, with each accumulator configured to obtain the inner product for one modulus mᵢ in one channel. In other words, for a moduli set [m₁,m₂, . . . , m_{M}], the accumulating unit 1408 comprises a total of M channels and a total of M accumulators.

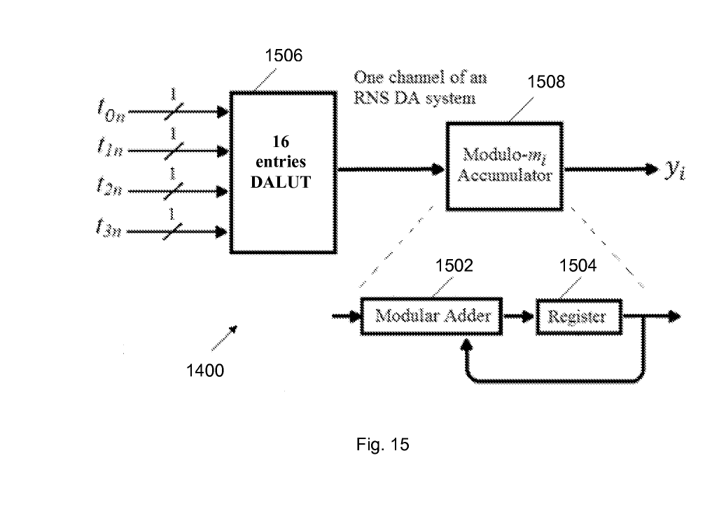

Thus, the units 1406, 1408 are each implemented as a set of M channels. FIG. 15 shows one channel of the units 1406, 1408 of the TC based DA-RNS system. The representation of the input signal in FIG. 15 comprises 4 input signal entries. The residues of these input signal entries are encoded with a plurality of bits tₖₙ in the TC format. In particular, the residues of the 1^{st}, 2^{nd}, 3^{rd} and 4^{th} input signal entries are respectively encoded with bits t₀ₙ t₁ₙ t₂ₙ and t₃ₙ.

The summation unit 1406 portion of the channel comprises a 16-entries DALUT 1506 and the accumulating unit 1408 portion of the channel comprises a Modulo-mᵢ Accumulator 1508. The accumulator 1508 is configured to obtain the inner product for the corresponding modulus mᵢ. As shown in FIG. 15, each accumulator 1508 further comprises a modular adder 1502 and a register 1504 whereby the modular adder 1502 is configured to perform the adding operations and the register 1504 is configured to store the outputs from the adding operations.

### BC Based Modular Adder

In one example, the modular adder 1502 as shown in FIG. 15 is in the form of a BC based modular adder.

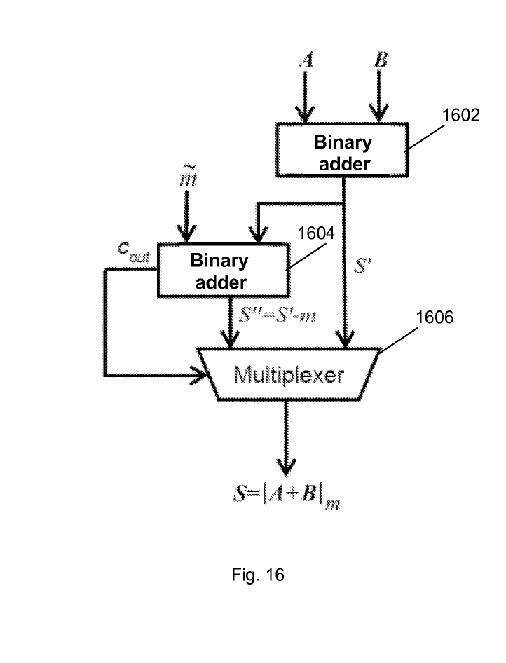

FIG. 16 (see reference [2]) shows a BC based modular adder for generic modulus values. This BC based modular adder employs BC based modular arithmetic and may be used as the modular adder 1502. For each modulus m used by the system 1400, the BC based modular adder comprises a channel with first and second binary adders 1602, 1604 for implementing the modular addition operation shown in Equation (24). The operand A in Equation (24) may be an accumulated value from a summation of past summation values whereas the operand B may be a subsequent summation value. As discussed above, these summation values are residue values of

$${f}_{{m}_{i}} ( {A}_{k} , {b}_{kn} ) = {\vert {\sum }_{k = 0}^{K - 1} {A}_{k} {b}_{kn} \vert}_{{m}_{i}} ,$$

in other words, residues from modulo operations.

The binary adders 1602, 1604 are used to perform the modular addition operation:

$${\vert A + B \vert}_{m} = \{ \begin{matrix}A + B & if A + B < m \\ A + B - m & otherwise\end{matrix} \qquad ( 24 )$$

In particular, the first binary adder 1602 is configured to perform an addition of the two operands, A and B to provide a sum S′. The second binary adder 1604 is configured to subtract the value of the modulus m from the sum S′. This subtraction is done by adding the sum S′ with the two's complement of m, i.e. \tilde{m}. The BC based modular adder further comprises a multiplexer 1606 whose output is controlled by a carry-out bit cₒᵤₜ from the subtraction done by the second binary adder 1604. The multiplexer 1606 is configured to determine whether the output of the BC based modular adder should be S=A+B or S=A+B−m based on the carry-out bit cₒᵤₜ. In other words, the multiplexer 1606 is in effect performing a modulo operation.

Although there is no carry propagation between channels for different moduli in the BC based modular adder, there is still a localized carry propagation occurring within each channel. This is because the residues to be summed by the BC based modular adder are encoded with the BC format whose operation is based on the principles of the binary adder. Furthermore, the BC based modular adder needs the carry-out bit cₒᵤₜ from the subtraction performed by the second binary adder 1604 in order to generate its final output. Therefore, the performance of the BC based modular adder depends very much on the carry propagation performance of binary adders 1602 and 1604.

Each of the first and second binary adders 1602, 1604 may be in the form of a ripple carry full adder which is slow but uses a simple logic structure, or a version of the carry-look-ahead full adder which is faster but at a much higher logic gates cost.

### One-Hot Code (OHC) Based Modular Adder

As mentioned above, the BC based modular adder is inefficient due to the carry propagation which is in turn due to the use of the BC format. This inefficiency may be overcome by using an alternative coding format.

In another example, the modular adder 1502 is in the form of a one-hot code based modular adder (OHC based modular adder) which uses a one-hot code (OHC) format for encoding the data.

The OHC format comprises n bits, but only 1 bit is asserted at any one time. Hence, it is also known as a 1-out-of-n encoding scheme. The OHC format is normally used for decoding address bits for LUTs. When it is used to encode residues in a RNS, each residue encoded in this manner may be referred to as a one-hot residue (OHR) [7]. In the OHC format, the value of the residue corresponds directly to the asserted bit position. Compared to the TCR, the OHR uses one extra bit in order to encode the value ‘0’. For example, in a modulus-7 system, a residue with a value of 5 may be represented with 7 bits with the bit pattern {0100000}, whereas a residue with a value of 0 may be represented with 7 bits with the bit pattern {0000001}.

While the value of an OHR is intuitively clear from its bit pattern, it lacks formal mathematical properties (e.g. base-1, base-2) and hence, it is difficult to use the OHR for general mathematical purposes. Nevertheless, the inventors of the present invention have found out the unique usefulness of the OHC for representing residues. In particular, the unique usefulness lies in that addition or subtraction of OHRs may be performed using a circular shifting technique which executes not only the addition or subtraction operation, but also the modulo operation on the output from the addition or subtraction.

For example, consider two modulus-7 residues r₁ and r₂ which have numerical values of 4 and 5 respectively. Expressing these residues in the OHC format, the following OHRs are obtained.

r₁=0010000

r₂=0100000 (25)

The modular sum of these two OHRs can be obtained by executing a circular shift operation on the bits of one of the OHRs, based on the value of the other OHR. For example, to sum r₁ and r₂, the bits representing r₁ are circular shifted by five bit positions to the left (since the value of r₂ is 5) such that the bit ‘1’ in the n=4 bit position wraps around the n=0 bit position and moves to the n=2 bit position. This is based on the assumption that in the plurality of bits representing r₁, the highest value bit is the leftmost bit in the n=6 bit position and the lowest value bit is the rightmost bit in the n=0 bit position. The output of the above-mentioned circular shifting is thus {0000100}, implying a numerical value of 2, which is consistent with the summing operation: |4+5|₇=2. As can be seen, the modulo operation is performed inherently via the wrapping involved in the circular shifting technique.

The OHC based modular adder may be implemented using shifters based circuits to perform the addition operation without carry propagation. As mentioned above, the circular shifting technique for adding or subtracting the OHRs performs not just the addition or subtraction but also the modulo operation on the output of the addition or subtraction. The implementation of the OHC based modular adder is thus simpler as compared to that of the BC based modular adder.

With the modular adder 1502 in the form of an OHC based modular adder and the summation values from the summation unit 1406 encoded in the BC format, the accumulator 1508 comprised in the accumulating unit 1408 can be said to have a hybrid design as elaborated below.

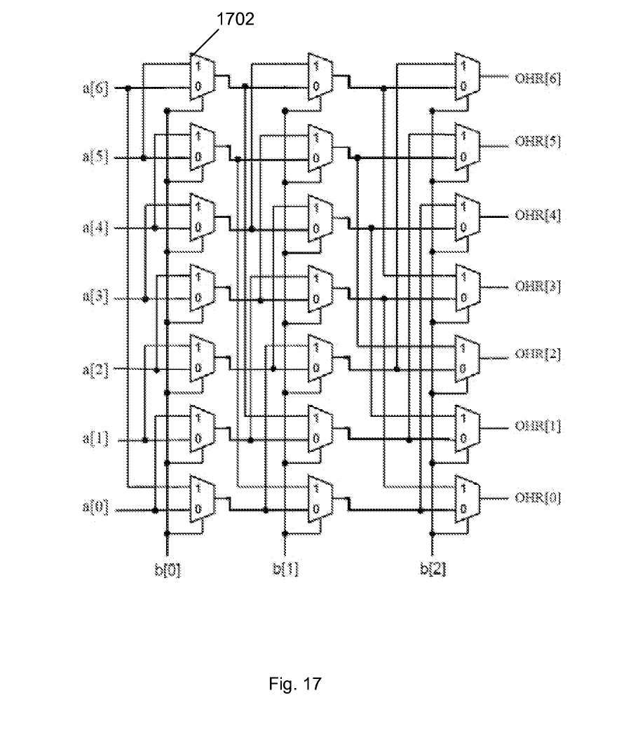

FIG. 17 shows the circuit schematic of an OHC based modular adder which may be used as the modular adder 1502. The OHC based modular adder in FIG. 17 is a modulo-7 adder. The OHC based modular adder comprises a plurality of multiplexers (see for example, multiplexer 1702) arranged to form a log-based circular shifter circuit (i.e. log shifter circuit). Input A is encoded with input bits a[n]=[a[0], a[1], . . . a[6]] in the OHC format. On the other hand, input B is encoded with input bits b[n]=[b[0], b[1], b[2]] in the BC format. The log shifter circuit is configured to apply circular shifting to the input bits a[n] of the OHC encoded input A with the amount of shift controlled by the input bits b[n] of the BC encoded input B. This effectively executes an addition function equivalent to |A+B|₇ with the modulo-7 operation performed as the OHR bits a[n] shift beyond the top MSB n=6 bit position and wrap around the bottom LSB n=0 bit position. The output bits OHR[n] are also in the OHC format. This is convenient especially if the output bits OHR[n] are to be used to address a LUT such as a binary encoder to present the output of system 1400 in the BC format.

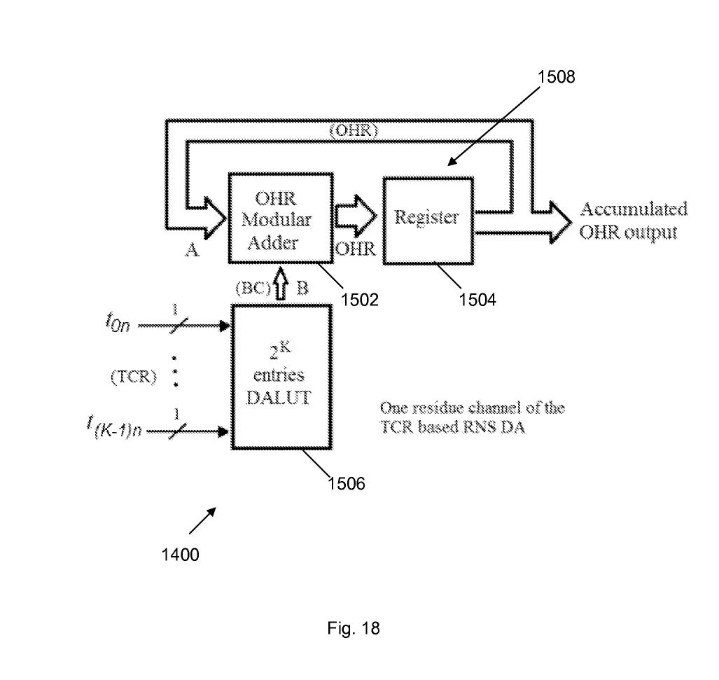

FIG. 18 shows one channel of the TC based DA-RNS system. The accumulator 1508 for each modulus comprises a modular adder 1502 in the form of an OHC based modular adder with a circuit schematic similar to that shown in FIG. 17, and a register 1504.

As shown in FIG. 18, the register 1504 is configured to provide input A to the OHC based modular adder whereas the DALUT 1506 of the summation unit 1406 is configured to provide input B to the OHC based modular adder. Input A is encoded in the OHC format and input B is encoded in the BC format (hence, the term “hybrid design”).

In particular, at the beginning of each accumulation execution cycle, the register 1504 provides a first input (set to zero) as input A to the OHC based modular adder whereas the DALUT 1506 provides a first summation value (for the modulus associated with the channel) as input B to the OHC based modular adder. The OHC based modular adder then generates a first augend from the first input and the first summation value. This first augend is then stored in the register 1504.

A plurality of iterations is then performed whereby in a first iteration, the register 1504 provides the first augend as input A to the OHC based modular adder and the DALUT 1506 provides a second summation value for the modulus as input B. The OHC based modular adder then generates a second augend from the first augend and the second summation value. The second augend is then stored in the register 1504. Similar steps are performed in the subsequent iterations for the remaining summation values for the modulus. In other words, the OHC based modular adder is configured to successively generate further augends in a plurality of iterations after generating the first augend. A further augend is generated in each iteration from a most recently generated augend and a subsequent summation value provided for the modulus. The register 1504 is configured to store the augend from each iteration and is further configured to provide the OHC based modular adder the most recently generated augend in each iteration.

Compared to the BC based modular adder, the OHC based modular adder based on shifters operates much faster as there are no logic gate delays involved in the operation. Neither does the OHC based modular adder have the carry propagation issue. Instead, the operating speed of the OHC based modular adder is determined solely by the delay of the signal passing through the multiplexers. In addition, the number of transistors used to implement the log shifter circuit of the OHC based modular adder is even lower than that for the BC based modular adder using the ripple carry full adder which is to date, the most area efficient (but slowest) implementation for a binary adder.

As mentioned above, the plurality of bits in each TCR has equal weights. Therefore, the TC based DA-RNS system can be configured to operate at 2-bit-at-a-time (2BAAT) [1] or at an even higher rate to compensate for the longer bit-length of the TCR.

FIG. 19 shows a channel of a TC based DA-RNS system configured to operate at 2BAAT. In the system of FIG. 19, the summation unit 1406 portion of the channel comprises first and second DALUTs 1902a, 1902b whereas the accumulating unit 1408 portion of the channel comprises first and second modular adders 1904a, 1904b. The first and second DALUTs 1902a, 1902b respectively provide first and second groups of summation values for the modulus associated with the channel, with the first group differing from the second group. Each modular adder 1904a, 1904b is driven by one group of bit-serial stream allocated from a DALUT 1902a, 1902b. In particular, the first DALUT 1902a provides the first group of summation values to the first modular adder 1904a whereas the second DALUT 1902b provides the second group of summation values to the second modular adder 1904b.

As shown in FIG. 19, the first and second modular adders 1904a, 1904b are cascaded to sum the first and second group of summation values provided by the two DALUTs 1902a, 1902b. More specifically, the first modular adder 1904a is configured to generate the augends with the first group of summation values. This is done in a manner similar to that of the modular adder 1502 as described above with reference to FIG. 18. However, in the 2BAAT design as shown in FIG. 19, in each iteration, prior to the register 1906 storing the augend, the second modular adder 1904b is configured to receive the augend from the first modular adder 1904a as its input A and add to this augend a summation value provided as input B from the second DALUT 1902b i.e. from the second group of summation values. The second modular adder 1904b performs this addition in the same manner as the first modular adder 1904a.

The order of addition is not important and the two groups of bit-serial streams i.e. the first and second group of summation values may respectively comprise the summation values arising from even bits and odd bits encoding the TCR of the input signal entries. Alternatively, the first and second group of summation values may respectively comprise the summation values arising from the lower half of an N-bit word (with

$$n = 0 , … , \frac{N - 1}{2} )$$

and upper half of the N-bit word (with

$$n = \frac{N + 1}{2} , … N - 1 )$$

encoding the TCR of the input signal entries. How the summation values are divided into the first and second groups usually depends on which division is more hardware convenient.

### Examples of TC Based DA-RNS Systems

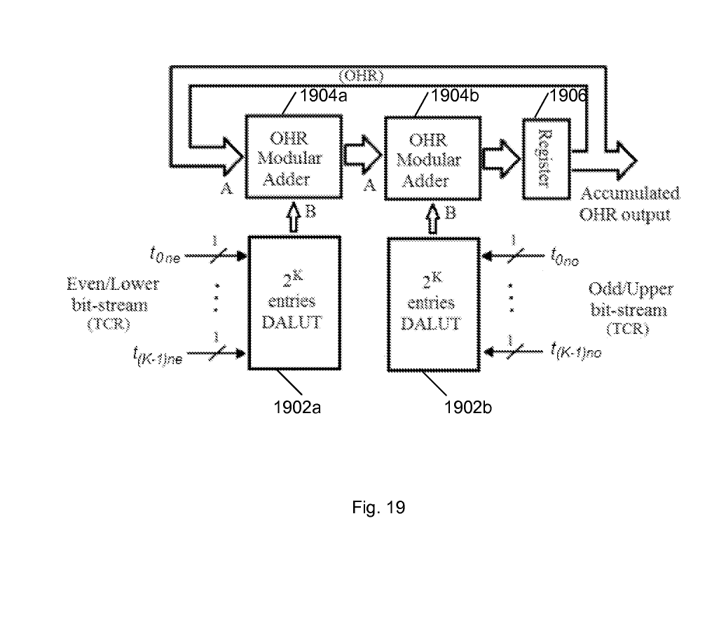

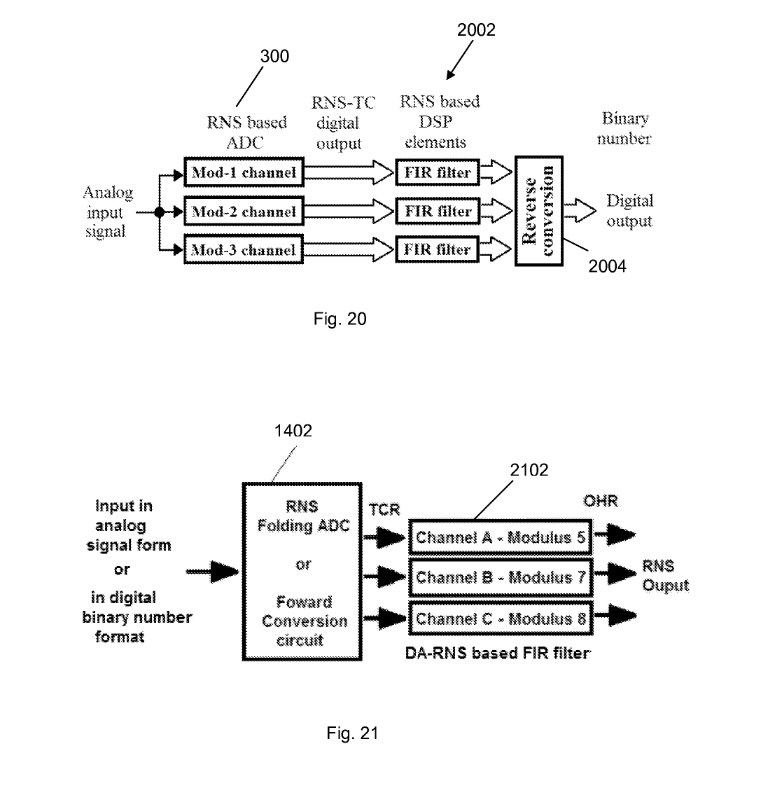

FIG. 20 shows an example TC based DA-RNS system comprising the conversion unit 1402 in the form of the ADC 300. The remaining units 1404, 1406, 1408 of the TC based DA-RNS system are comprised in a plurality of DA-RNS based FIR filters 2002. FIG. 20 illustrates how the channels of the ADC 300 (Mod-1 channel, Mod-2 channel, Mod-3 channel) may be integrated with the individual RNS-based FIR filters 2002 to perform digital signal processing (DSP) based filtering function. As shown in FIG. 20, the output from the TC based DA-RNS system may be converted to the more conventional binary number representation for further computation. In particular, the TC based DA-RNS system in FIG. 20 is connected to a reverse conversion unit 2004 to perform a reverse conversion on the output of the DA-RNS based FIR filters 2002 to produce output data in a binary number representation.

FIG. 21 shows another example TC based DA-RNS system. In this system, the conversion unit 1402 may be in the form of the ADC 300 or any other circuit capable of outputting data in the TCR format (for example, a Binary-to-RNS conversion circuit) whereas the remaining units 1404, 1406, 1408 are comprised in a single DA-RNS based FIR filter 2102. Three residue channels, one for each modulus, are used to implement the DA-RNS based FIR filter 2102. The output data from the DA-RNS based FIR filter 2102 are in the OHC format.

### Simulation Results

The DA-RNS based FIR filter in FIG. 21 is implemented and its performance is analyzed.

### FIR Filter Implementation

A FIR lowpass filter output y[n] is related to its input signal x[n] through the filter coefficients Aₖ as follows:

$$y [ n ] = {\sum }_{k = 0}^{K - 1} {A}_{k} x [ n - k ] \qquad ( 26 )$$

As shown in Equation (26), the operation of the FIR low pass filter comprises multiple inner product computations as a series of input signal entries are made available to the filter.

A 4th order DA-RNS based FIR digital low pass filter designed using the Parks-McClellan algorithm has coefficients as shown below.

y[n]=3x[n]+11x[n−1]+15x[n−2]+11x[n−3]+3x[n−4] (27)

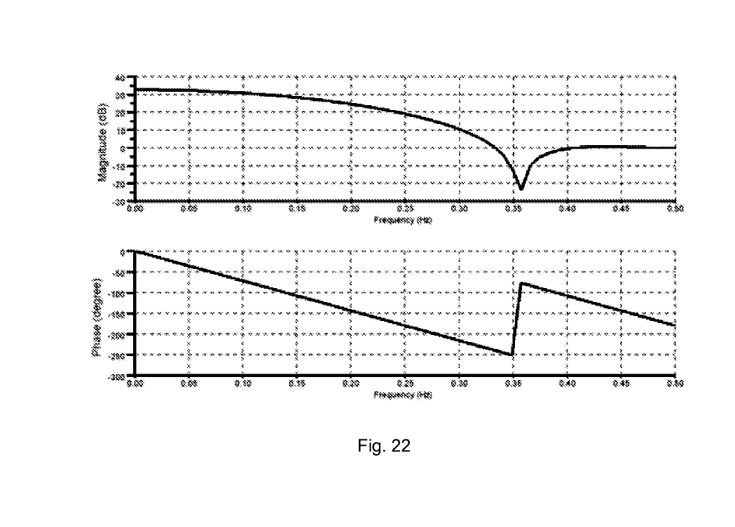

The frequency response of this FIR filter is shown in FIG. 22. The corner frequency is chosen to be about 0.1 of the filter's operating frequency fₛ, with a maximum attenuation of −55 dB below the passband occurring at 0.35 fₛ.

To demonstrate the operation of this filter, an input data sequence comprising a plurality of input signal entries is generated. The input data sequence comprises a first signal component with a frequency at about 0.06 fₛ, i.e. within the passband of the filter and a second signal component with a frequency located at about 0.35 fₛ. To simplify the numerical conversion between the input signal entries in the form of data binary numbers and their RNS representations later on, the values of the input signal entries are rounded to integer values. The values of the input signal entries are also kept within bounds such that the resultant output dynamic range can be adequately covered using a [5,7,8] moduli set. An example input data sequence generated with 51 points is as follows:

x[n]={1,1,2,3,3,5,5,5,6,5,5,5,3,4,2,1,2,0,0,1,0,2,2,2,5,4,5,6,5,6,5,4,4,2,2,2,0,1,0,0,2,1,2,4,3,5,6,5,6,5} (28)

The input data sequence x[n] is then applied to the 4th order FIR filter, and the output y[n] obtained is as follows:

y[n]={3,14,32,57,86,118,154,187,212,226,230,226,212,190,165,133,100,71,47,28,17,21,39,61,89,125,162,194,215,230,237,230,212,183,147,114,86,61,39,21,17,28,47,71,100,133,168,201,227,237,233} (29)

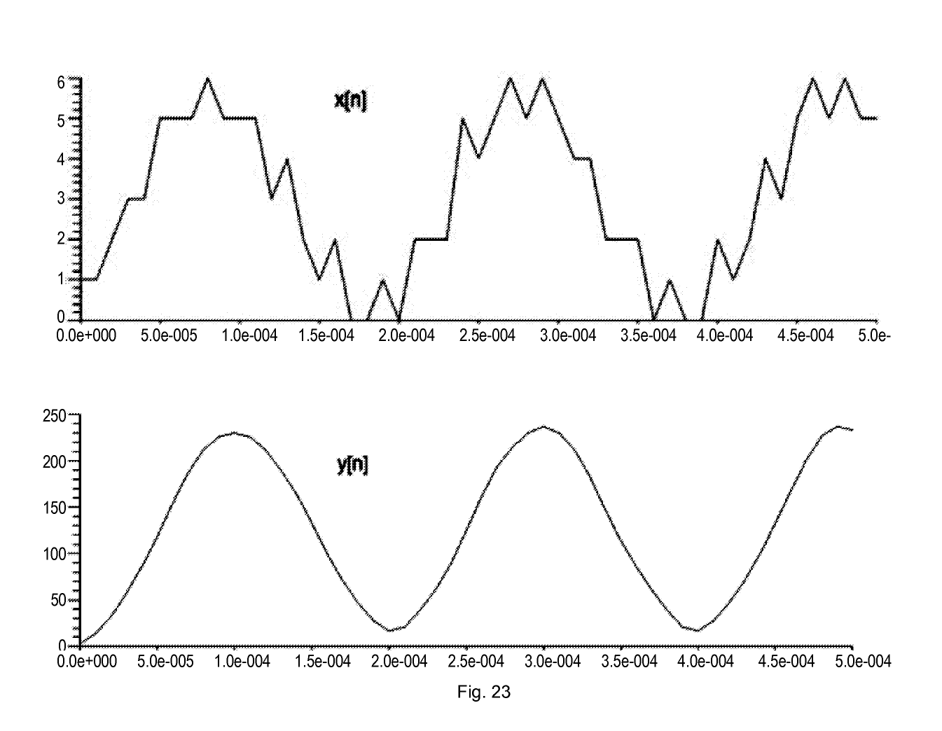

The time domain response of the FIR filter with the input data sequence is also generated using a simulator for visual confirmation of its filtering effect and its operation as intended. The simulated input and output waveforms are shown in FIG. 23. As shown in FIG. 23, the input x[n] shows a significant amount of irregularity due to the high frequency components as well as the quantization effect of rounding the values of the input signal entries to integer values. The output waveforms show that the FIR filter is performing an adequate job of filtering the input data sequence as intended.

The FIR filter designed is next translated to the DA-RNS based FIR filter in FIG. 21. A [5,7,8] moduli set that provides a DR of [0,280) is chosen for the translation. This moduli set is sufficient to accommodate the maximum output value observed in Equation (29) obtained through the simulation above.

The summation unit 1406 of the DA-RNS based FIR filter comprises three DALUTs, one for each channel corresponding to a modulus. The DALUT for each of the three channels is derived by calculating the summation values using Equation (22) with the plurality of filter coefficients Aₖ as follows:

$${f}_{{m}_{i}} ( {A}_{k} , {t}_{kn} ) = {\vert {\sum }_{k = 0}^{4} {A}_{k} {t}_{kn} \vert}_{{m}_{i}} \qquad ( 30 )$$

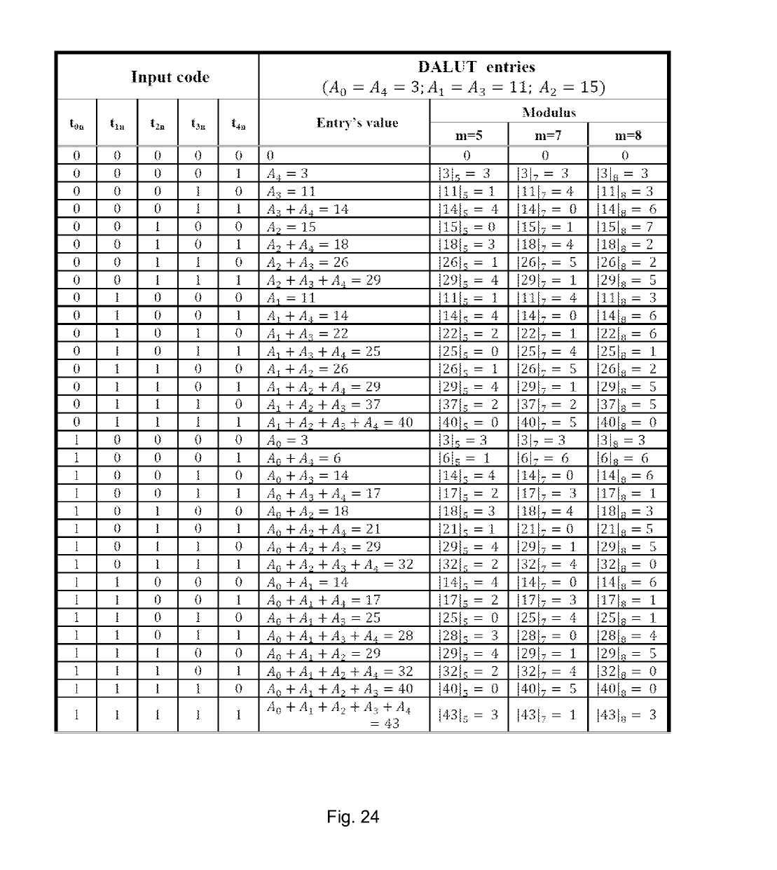

FIG. 24 illustrates a table tabulating the entries (comprising the summation values) of the DALUTs for all three channels in the exemplary DA-RNS based FIR filter. Note that the DALUT for each channel comprises only a subset of the table shown in FIG. 24. As the DA-RNS based FIR filter comprises 5 coefficients, there are 32 rows in the table of FIG. 24 and three columns, one for each channel corresponding to one of the moduli [5,7,8].

A step-by-step calculation of the DA-RNS based FIR filter response is now presented to demonstrate the filter operation.

FIG. 25 illustrates a table tabulating the first twenty input signal entries to the DA-RNS based FIR filter with the input signal entries in the RNS format. For brevity, only the first seven input signal entries (i.e. the first seven data from the table of FIG. 25) are used in the following numerical calculations to validate the response of the DA-RNS based FIR filter.

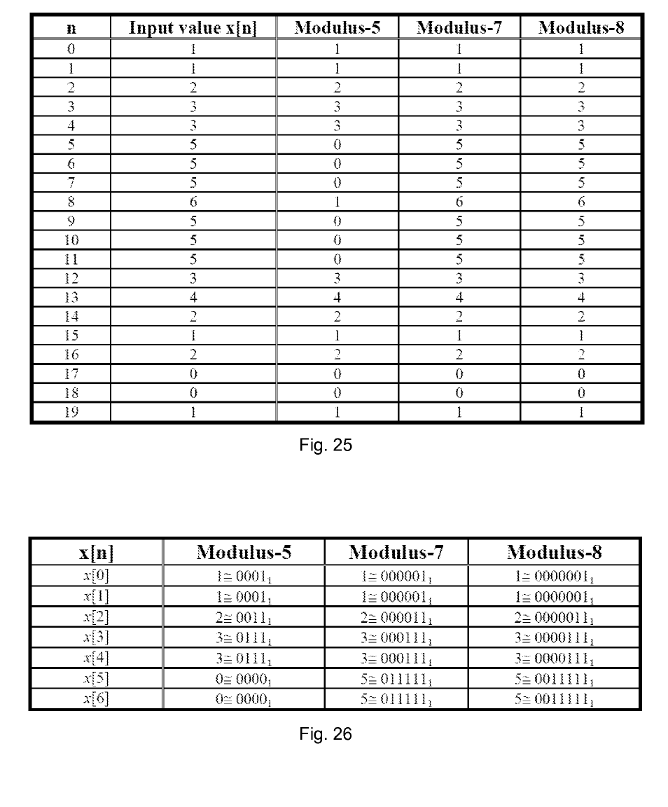

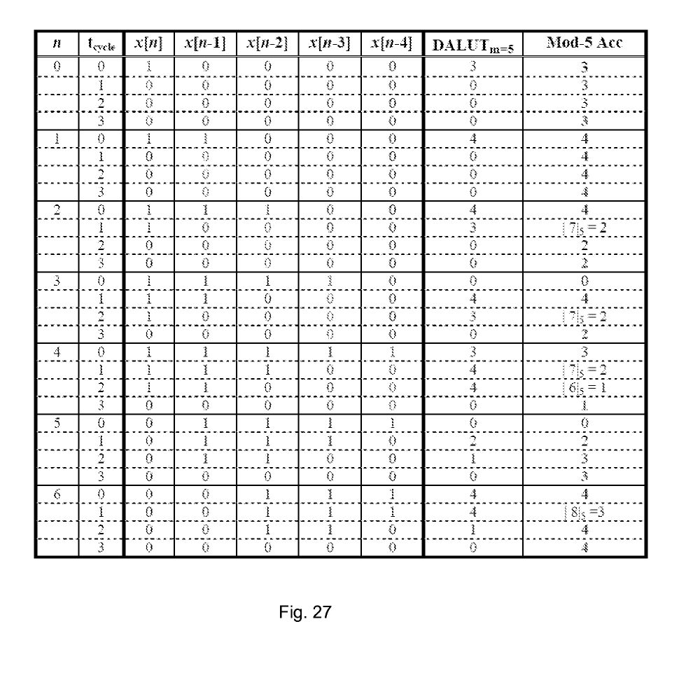

FIG. 26 illustrates a table tabulating the residues of the above-mentioned first seven input signal entries with the residues encoded in the TC bit-parallel format. These residues encoded in the TC bit-parallel format are then sent by the conversion unit 1402 to the formatting unit 1404 for conversion to the bit-serial format, and then in a 1 BAAT bit-serial manner to the summation unit 1406 in the DA-RNS based FIR filter for addressing the respective modulus's DALUT.

In particular, starting with n=0, the first group of residues sent by the conversion unit 1402 are residues of x[0], x[−1], x[−2], x[−3] and x[−4]. At n=1, the second group of residues sent by the conversion unit 1402 are residues of x[1], x[0], x[−1], x[−2] and x[−3]. In general, the residues sent by the conversion unit 1402 will progressively incorporate residues of a subsequent x[n] with residues of 4 prior input signal entries. In a practical casual system, input signal entries prior to x[0] are considered to have a value equal to 0. Hence in this case, the response of the DA-RNS based FIR filter will reach a steady state at n=4. The following shows the detail of the data operation for the three channels, A, B and C corresponding to the three moduli 5, 7 and 8.

### i) Channel a for Modulus-5

FIG. 27 illustrates a table showing the sequence of bits sent to the DA-RNS based FIR filter. The input data sequence is sent in a 1 BAAT bit-serial manner by the formatting unit 1404 to the summation unit 1406 of the DA-RNS based FIR filter to access the DALUT associated with modulus 5. The entries in the DALUT are shown in the table of FIG. 24.

The DALUT outputs corresponding to each row of bits received i.e. summation values provided by the summation unit 1406 are indicated under the “DALUT entries (m=5)” column. For each time instance n, four summation values are provided and are modulo-5 accumulated over four clock cycles as shown under the “Mod-5 Acc” column in the table of FIG. 27. In other words, the output for each time instance n results from four rows of bits providing four summation values, and from the modulo-5 accumulation of these four summation values over 4 clock cycles. This is with the assumption that the execution of the summation and accumulation operations can be completed in 4 clock cycles. In practice, the amount of delay on the output depends on the sampling intervals and the speed of the processing clock. In certain cases, the time interval between the sampling instances may be longer than 4 clock cycles, and the summation and accumulation execution process does not cause any additional delay.

The output from the 4^{th} clock cycle (i.e. at t_{cycle}=3) is the inner product for the modulus 5 derived from residues of the input signal entries x(n), x(n−1), x(n−2), x(n−3) and x(n−4) at time instance n and the filter's coefficients Aₖ. From the table of FIG. 27, the filter's modulus-5 channel output for n=0 to 6 are as follows:

y₅[n]={3,4,2,2,1,3,4} (31)

### ii) Channel B for Modulus-7

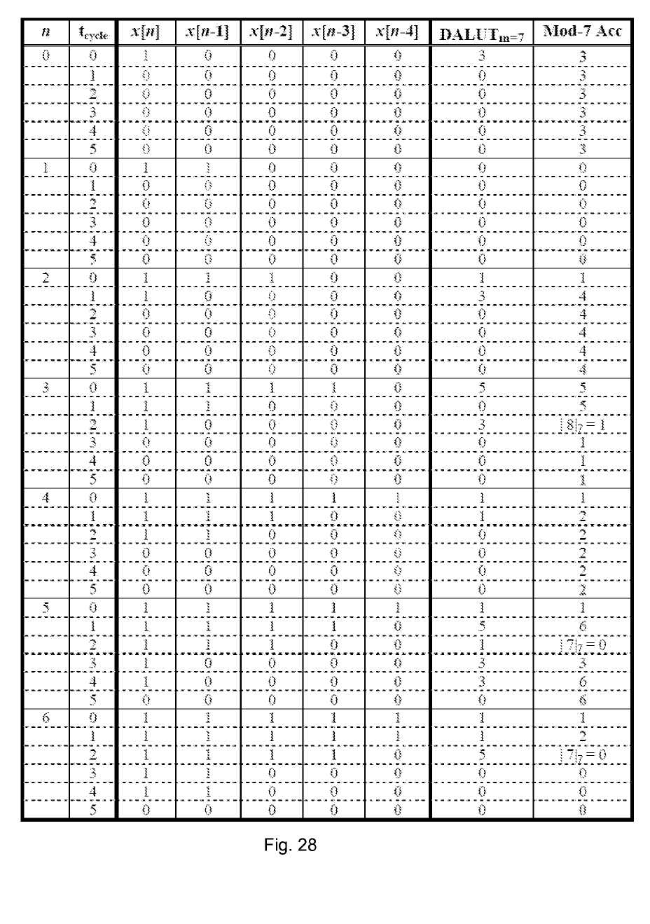

Similar steps are used to derive the output of the modulus-7 channel B. As the TCR bit-length is 6 bits long for this channel, the resultant inner product for the modulus 7 is obtained in the 6^{th} clock cycle (indicated as t_{cycle}=5) as shown under the “Mod-7 Acc” column in the table of FIG. 28. From the table in FIG. 28, the filter's modulus-7 channel B output for n=0 to 6 are as follows:

y₇[n]={3,0,4,1,2,6,0} (32)

iii) Channel C for Modulus 8

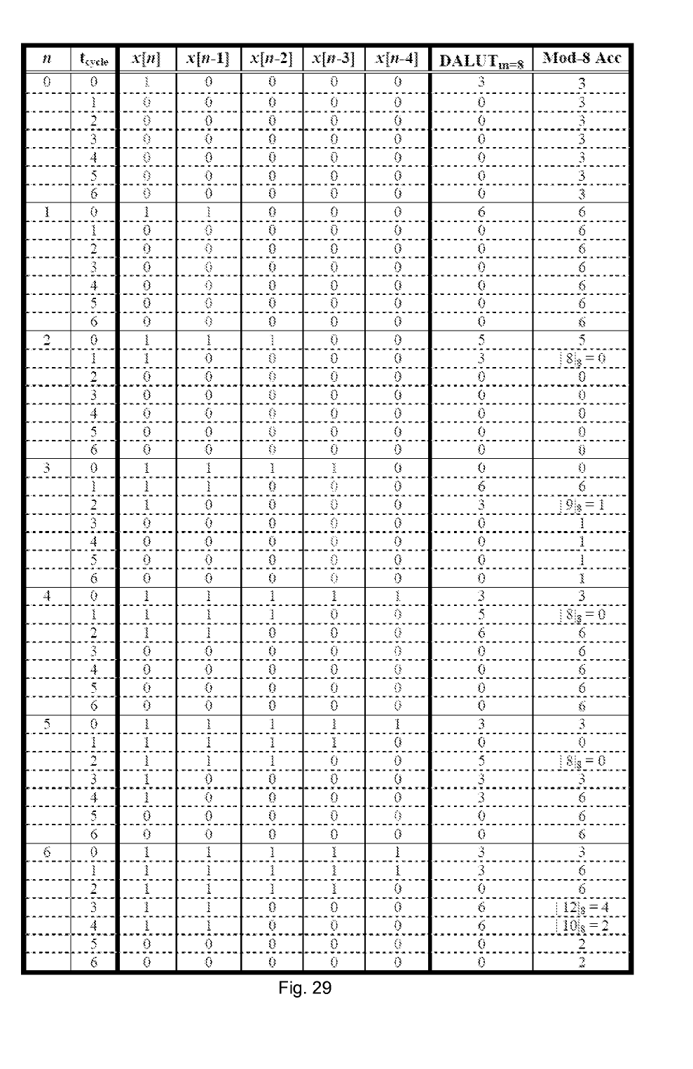

Similar steps are used to derive the output of the modulus-8 channel C. As the TCR bit-length is 7 bits long for this channel, the resultant inner product for the modulus 7 is obtained in the 7^{th} clock cycle (indicated as t_{cycle}=6) as shown under the “Mod-8 Acc” column in the table of FIG. 29. From the table in FIG. 29, the filter's modulus 8 channel C output for n=0 to 6 are as follows:

y₈[n]={3,6,0,1,6,6,2} (33)

Consolidating the outputs of all three channels from Equations (31), (32) and (33) for n=0 to 6, the output data sequence of the FIR filter, in RNS representation is as follows.

For n=0 to 6:

y[n]={<3,3,3>,<4,0,6>,<2,4,0>,<2,1,1>,<1,2,6>,<3,6,6>,<4,0,2>} (34)

The correctness of this RNS based output can be confirmed by performing a reverse conversion using the Chinese Remainder Theorem (CRT) to find its binary representation. The CRT's reverse conversion formula is as follows (see reference [2]):

$${Y = \vert {\sum }_{i = 1}^{M} \vert {P}_{i} {\vert {N}_{i} {y}_{i} \vert}_{{m}_{i}} \vert}_{P} \qquad ( 35 )$$

where
P=m₁m₂ . . . m_{M},
Pᵢ=P/mᵢ
Nᵢ=|Pᵢ⁻¹|ₘ_{ᵢ}, multiplicative inverse of Pᵢ mod mᵢ such that |NᵢPᵢ|ₘ_{ᵢ}=1.

Applying the values used in this example, the CRT expression of Equation (35) becomes:

Y=|56|y₁|₅+40|3y₂|₇+35|3y₃|₈|₂₈₀ (36)

Substituting the residues digits values i.e. RNS representation of the RNS-based FIR filter as shown in Equation (34) into Equation (36), the binary representation of the y[n] output can be obtained as follows.

Starting with n=0:

$$\begin{matrix}y [ 0 ] = 〈 3 , 3 , 3 〉 \\ ≅ \vert 56 \vert 3 {\vert}_{5} + 40 \vert 3 \times 3 {\vert}_{7} + 35 \vert 3 \times 3 {{\vert}_{8} \vert}_{280} \\ = 3\end{matrix} \qquad ( 37 )$$

The other binary values corresponding to n=1 to 6 can be similarly calculated and the y[n] output values for these n=1 to 6 are as follows.

y[1]= [symbol] 4,0,6 [symbol] ≅14

y[2]= [symbol] 2,4,0 [symbol] ≅32

y[3]= [symbol] 2,1,1 [symbol] ≅57

y[4]= [symbol] 1,2,6 [symbol] ≅86

y[5]= [symbol] 3,6,6 [symbol] ≅118

y[6]= [symbol] 4,0,2 [symbol] ≅154 (38)

These calculated values are exactly the same as the first seven values given in Equation (29), hence confirming the accurate operation of the DA-RNS based FIR filter and the TC based DA-RNS system.

### FIR Circuit Simulations

To further demonstrate the practical feasibility of the TC based DA-RNS system, circuit level simulations using a PSPICE simulator are performed.

### 1 BAAT Operation for Modulus-5 Channel A

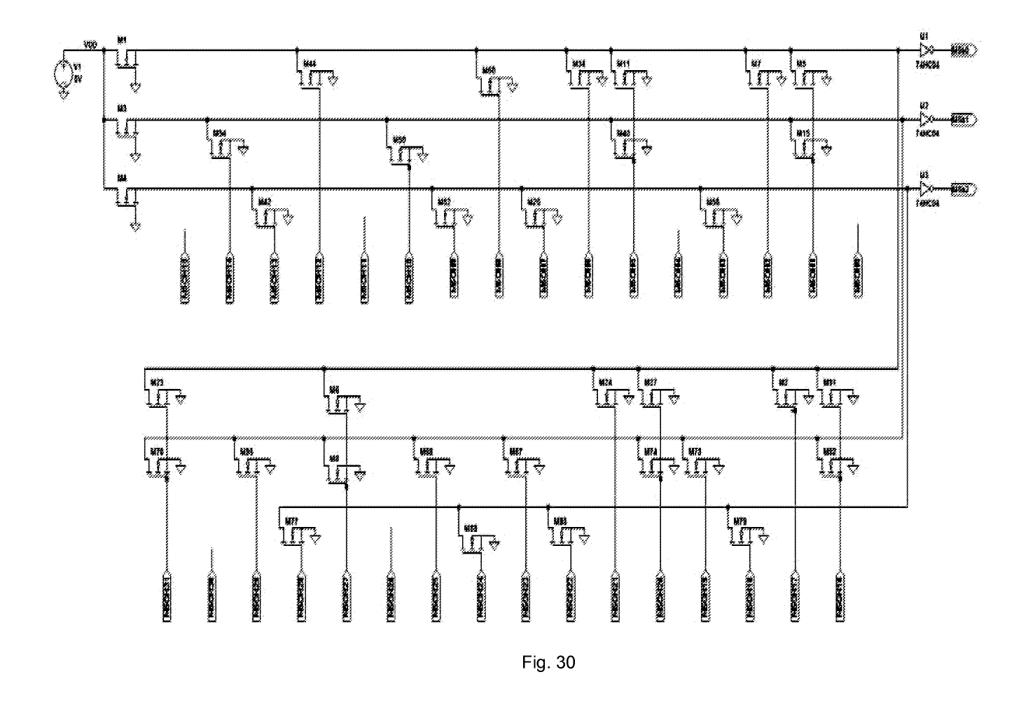

FIG. 30 shows one implementation of the modulus-5 DALUT in the DA-RNS based FIR filter of FIG. 21 with entries values shown in FIG. 24. As shown in FIG. 30, the DALUT is constructed using a CMOS circuit.

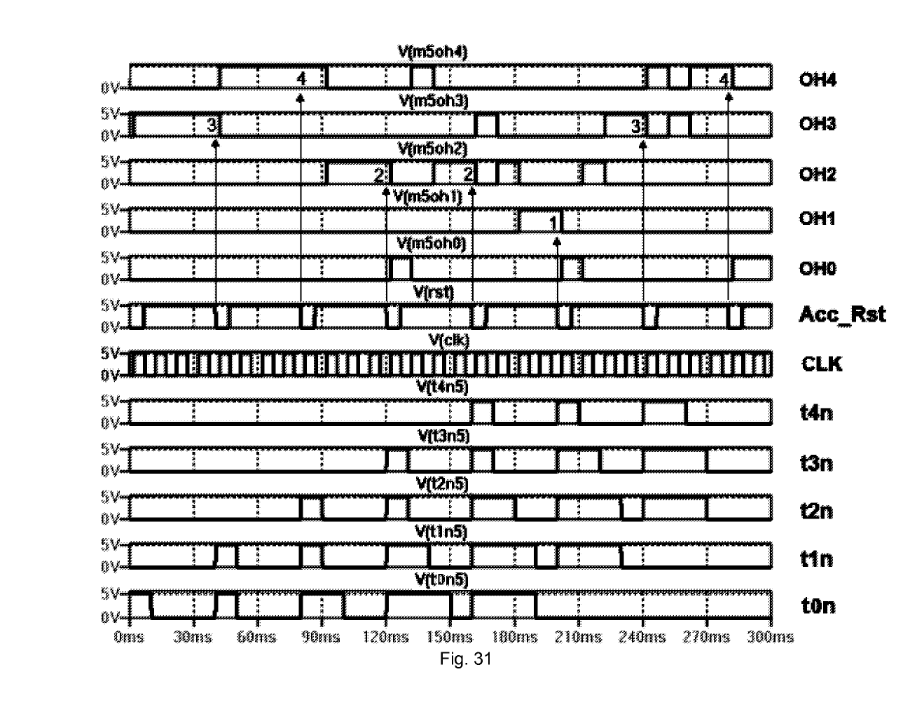

The 1BAAT design for the TC based DA-RNS system is shown in FIG. 18. The modulus-5 channel of the RNS-based FIR filter in FIG. 21 is based on this design and its operation is simulated using a PSPICE simulator. The captured timing diagram for this filter is shown in FIG. 31. In the simulation, a signal, Acc_Rst is used to reset the content of the accumulator's register 1504 to 0 prior to computing the accumulation for each time instance n, with each accumulation taking 4 clock cycles. This Acc_Rst signal hence may be used as a reference signal to indicate the output of the DA-RNS based FIR filter. As shown in FIG. 31, the output of the filter in OHC format appears as the sequence {3,4,2,2,1,3,4}, matching exactly the calculated values given in Equation (31).

### 2BAAT Operation for Modulus-7 Channel B and Modulus-8 Channel C

As the bit-lengths used by the modulus 7 and 8 channels are longer, if these channels are implemented using the 1 BAAT, the accumulation for each time instance n would take 6 and 7 clock cycles respectively, as indicated in the tables of FIGS. 28 and 29. Therefore, a 2BAAT design is used for the modulus 7 and 8 channels instead. The 2BAAT design for a TC based DA-RNS system is shown in FIG. 19.

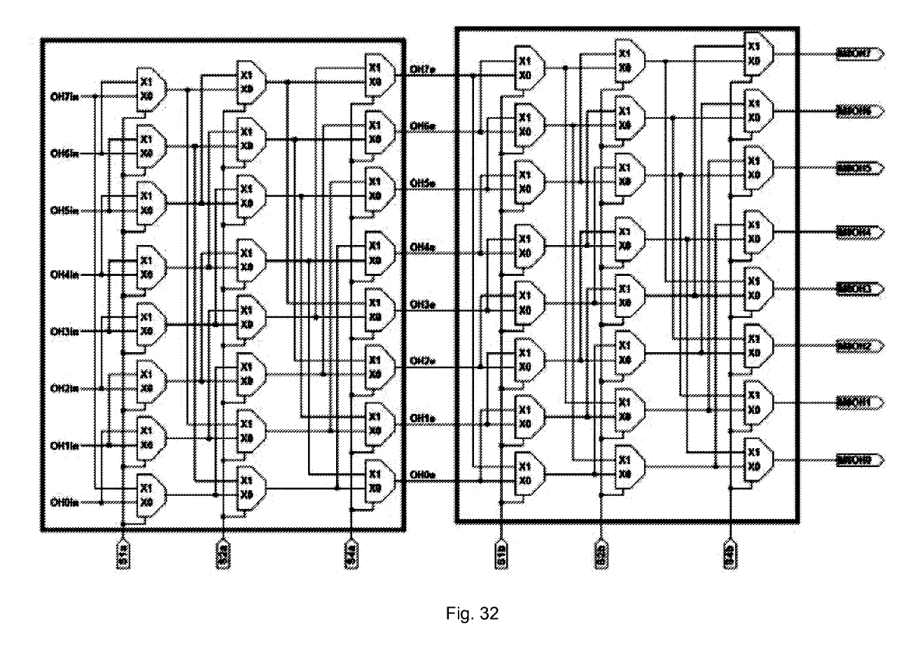

The following presents the circuit and simulation results of the 2BAAT operation for the modulus-8 channel C. FIG. 32 shows a circuit arrangement for the modular adders in each accumulator in the DA-RNS based FIR filter for the modulus 7 and 8 channels. Two OHC based modulus-8 adders are connected in cascade as shown in FIG. 32 to enable the 2BAAT operation. These cascaded adders are arranged in the manner as shown in FIG. 19.

To demonstrate the flexibility of the TC based DA-RNS system, two bit-serial streams are created for each channel. In particular, for the modulus-8 channel, a first bit-serial stream is created from the lower four bits of the TCR of each input signal entry, and a second bit-serial stream is created from the upper three bits of the TCR of each input signal entry. The second bit-serial stream is padded with one extra bit ‘0’ to balance the two bit-serial streams. These two bit-serial streams are then sent in parallel in the 2BAAT bit-serial manner to the summation unit 1406 which contain the two DALUTs for the modulus-8 channel of the DA-RNS based FIR filter. The BC encoded output i.e. summation values provided by each of the two DALUTs is then fed to respective ones of the cascaded modulus-8 adders of FIG. 32 for the adders to perform the inner product calculation for the modulus-8 channel C.

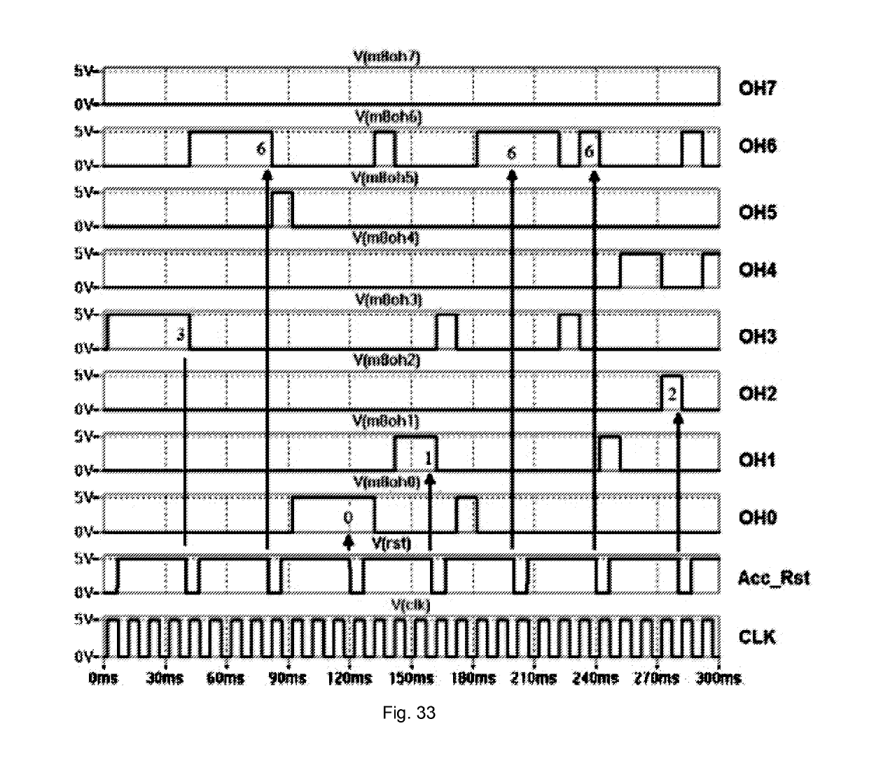

FIG. 33 shows the timing diagram captured for the channel C 2BAAT based operation, whereby each inner product computation i.e. accumulation operation is completed in four clock cycles. This is the same duration taken by the accumulation operation of the modulus-5 channel implemented with the 1 BAAT design. The output values of the modulus-8 channel are captured on the falling edge of the Acc_Rst signal. As expected, the output of the modulus-8 channel in OHC format appears as the sequence {3,6,0,1,6,6,2}, matching exactly the calculated values shown in Equation (33).

The simulation results above confirm the practical feasibility of the TC based DA-RNS system. Using a combination of TC, BC and OHC formats, an efficient means to perform DA-RNS based inner product calculation can be achieved by the TC based DA-RNS system. To compensate for the longer bit-lengths of the TCRs, higher BATT rates can be used. This possibility arises as the bits in the TCRs have equal weights and the operating principles of the TC based DA-RNS system are not complex.

### Performance Evaluation

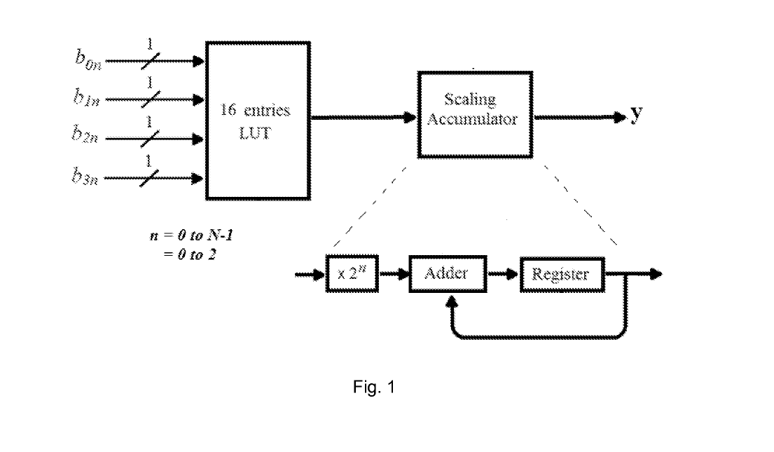

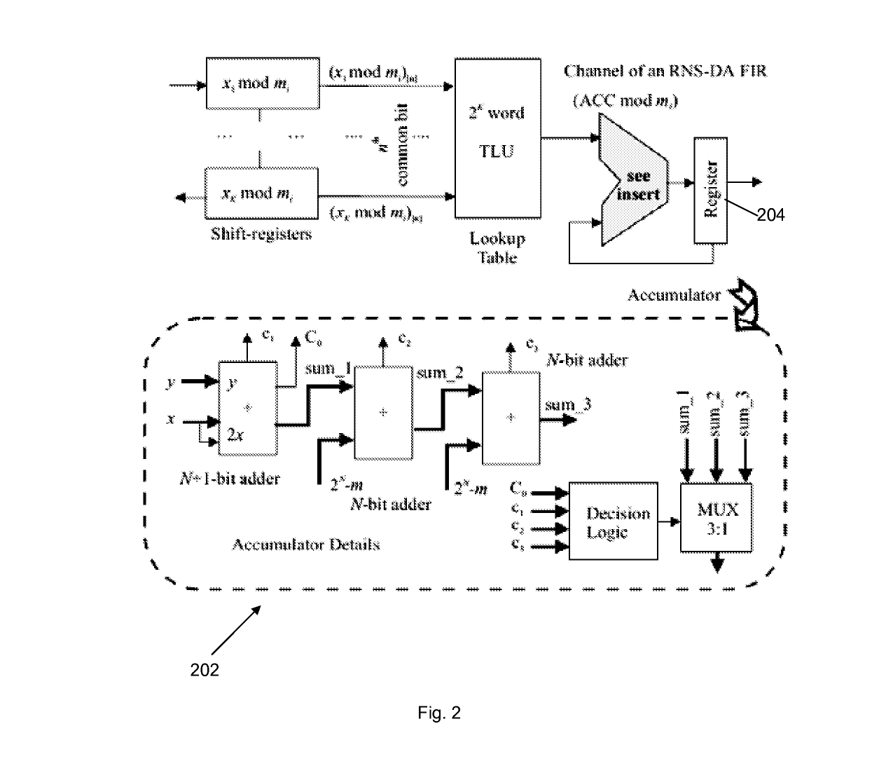

An advantage of the TC based DA-RNS system lies in its simple accumulation operation during the computation of the inner product. Compared to the scaling accumulator for the BC based DA system (see FIG. 1) and the modular scaling accumulator for the BC based DA-RNS system (see FIG. 2), the TC based DA-RNS system is less complex as it requires only modular addition. Although each TCR has a longer bit-length (which seems to imply the need for more clock cycles as compared to the BC based DA system and the BC based DA-RNS system), in practice, due to the 2ⁿ scaling and its modulo operations, the BC based DA system and BC based DA-RNS system may actually require a greater number of clock cycles than the TC based DA-RNS system. In other words, the need for 2ⁿ scaling operations in the BC based DA and 2ⁿ modulo operations in the BC based DA-RNS systems nullify their advantage of shorter bit-lengths over the TC based DA-RNS system.

The superiority of the TC based DA-RNS system over the BC based DA and BC based DA-RNS systems thus hinges on the effectiveness of its modular adder. This section compares the performance and complexity of the OHC based modular adder against the BC based modular adder comprising binary adders.

A BC based modular adder requires two binary adders of either 3-bit or 4-bit arranged in the manner as shown in FIG. 16. It is possible to reduce the latency of the BC based modular adder by using only one adder with a parallel design [8] but this reduction is at a higher hardware cost. To implement a BC based DA system (i.e. non-RNS type such as the system shown in FIG. 1), binary adders of appropriate bit-length (e.g. 12-bit binary adders) to accommodate the DR, including the 2ⁿ scaling factor are required.

Two standard representative binary adders may be used in the BC based modular adder for the comparison against the OHC based modular adder. These are the ripple carry full adder and the carry-look-ahead full adder. The ripple carry full adder is the most hardware efficient but slowest implementation of the binary adders, while the carry-look-ahead full adder is one of the fastest binary adder but has a high hardware circuit complexity. Note that special modular adders that are optimized for specific classes of moduli (e.g. 2ⁿ and the likes) are not considered in the comparison as the purpose of the comparison is to evaluate adders that may be employed in systems using generic moduli.

FIG. 34(a) shows a logic gate implementation for one bit of the ripple carry full adder [9]. A 3-bit or 4-bit ripple carry full adder may use 3 or 4 of such a circuit.

A 4-bit binary carry-look-ahead full adder may be implemented with the circuit in FIG. 34(a) for the 1^{st} bit. For the 2^{nd}, 3^{rd} and 4^{th} bits, the 4-bit binary carry-look-ahead full adder may be implemented with the portion of the circuit shown within the dotted box in FIG. 34(a) replaced with the circuits shown in FIG. 34(b), FIG. 34(c) and FIG. 34(d) respectively.

To implement the OHC based modular adder, moduli with values varying between 5 and 13 are used. With such moduli, the circuits for the OHC based modular adder may be realized in a more practical manner in terms of the hardware implementation. Furthermore, such moduli can form a moduli set with a dynamic range of more than 2¹⁶, sufficient for most practical cases. In an OHC based modular adder using a modulus value of m, the number of multiplexers needed in the log shifter circuit with the arrangement as shown in FIG. 17 is equal to m┌ log₂ m┐.

Gate count comparison between the OHC based modular adder and the BC based modular adder is difficult as the multiplexers in the OHC based modular adder are usually realized using transistor based circuits such as the 4-transistor based CMOS Transmission Gate or the 2-transistor based Pass-Transistor logic. Hence, it is more appropriate to compare the hardware complexity of the OHC based modular adder and the BC based modular adder in terms of transistor count. However, this does not reflect the complexity involved in the wiring of the underlying circuits. The transistor count comparison is performed based on the following: a total of 6 transistors is used for each 2-input XOR logic gate, a total of 4 transistors is used for each of all other types of 2-input logic gates, a total of 2 transistors is used for each extra input pin and a total of 2 transistors is used for each NOT gate. Each multiplexer is considered to comprise the 4-transistor based CMOS transmission gate as this is a fairly conservative design. One NOT gate is shared among all multiplexers to generate the internal complement shift control signal.

Critical path gate-delay comparison is based on the longest path that a signal propagates through the circuits of the OHC based modular adder and the BC based modular adder. For the BC based modular adder, this is equal to the delay through the two binary adders 1602, 1604 to generate the S″ value for the output multiplexer 1606 as shown in FIG. 16. A binary adder in the form of a ripple carry full adder has a propagation delay equal to (2n+2) due to the carry bit propagation [9]. For a binary adder in the form of a carry-look-ahead full adder, the most optimum implementation will be 6 gate-delays independent of the number of bits [2], although in practice, the gate-delays may be longer due to the higher fan-in of higher bit logic gates and wiring length. The OHC based modular adder does not use any combination logic gates in its implementation. Its latency is hence solely dependant on the signal propagation delay through the multiplexers.

To provide a more definitive comparison, a HPSICE simulation is performed to implement a ripple carry full adder based on 65 nm technology to determine the time a signal takes to travel the critical path B₀ to C₀ shown in FIG. 34(a). This time corresponds to the carry propagation delay of a 1-bit for the ripple carry full adder. From the HPSICE simulation, a carry propagation delay of about 78.7 psec for the critical path B₀ to C₀ is obtained. As this critical path is equivalent to 4 gate-delays (2 gate-delays for the XOR gate and 1 gate-delay for each of the AND and OR gates), the estimated time equivalent to 1 gate-delay is hence about 20 psec. For example, since the propagation gate-delay of an n-bit ripple carry full adder is about (2n+2) gate-delays, a 3-bit ripple carry full adder will have a propagation gate-delay of about (2×3+2)=8 gate-delays which is equivalent to approximately 160 psec. For a 3-bit BC based modular adder comprising ripple carry full adders, the total propagation delay will be twice as long due to its 2 binary adders connected in series. In other words, the 3-bit BC based modular adder will have a total propagation delay of about 320 psec and a 4-bit BC based modular adder will have a total carry propagation delay of about (2×4+2)×20×2=400 psec. The above information will be used for the comparison between the BC based modular adder and the OHC based modular adder.

A HSPICE simulation is also performed to estimate the signal propagation delay through a log shifter circuit comprising four multiplexers in cascade (such a log shifter circuit is suitable for a OHC based modular adder using moduli up to a value of 15). The latency or signal propagation delay measured via the simulation is 8.8 psec, in other words, an estimate of 2.2 psec delay is incurred as the signal travels through each multiplexer. The comparisons in this section are performed based on this estimate to obtain some indicative performance values, and to verify that using the OHC based modular adder is advantageous as compared to the BC based modular adder. However, note that in practice, the propagation delay of the signal through each multiplexer may vary depending on the actual output load, layout related parasitic effect, and skill of the designer.

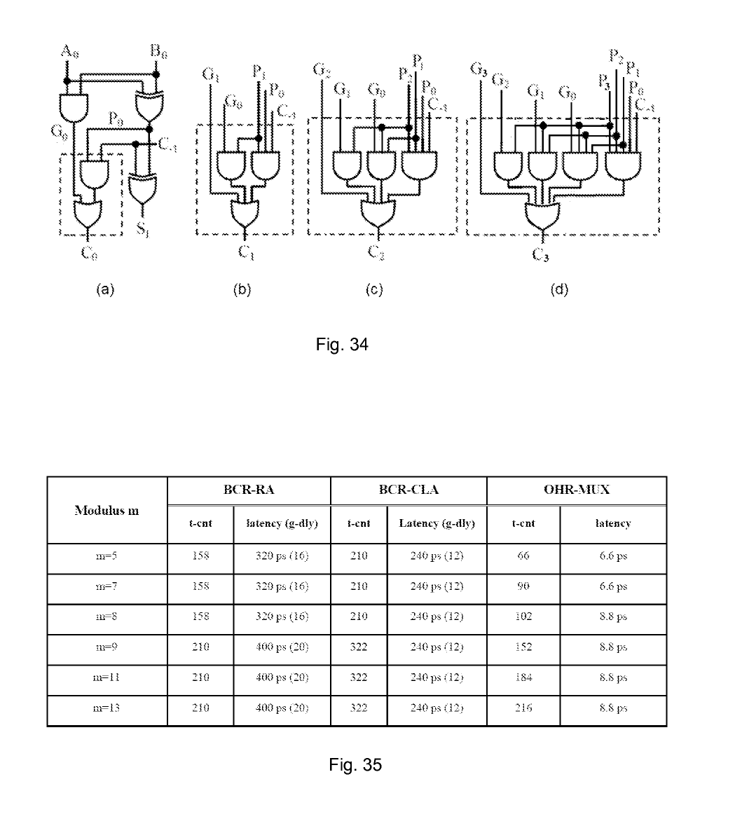

FIG. 35 illustrates a table tabulating characteristics of a BC based modular adder comprising ripple carry full adders (BCR-RA), a BC based modular adder comprising carry-look-ahead full adders (BCR-CLA) and an OHC based modular adder comprising the log shifter circuit (OHR-MUX)). In particular, the table of FIG. 35 shows the transistor counts (t-cnt), and latency in psec (ps) or gate-delay (g-dly) for the modular adders using different moduli. The table in FIG. 35 is derived based on the estimate of a 2.2 psec delay through each multiplexer and the estimate of 20 psec for 1 gate-delay.

As shown in FIG. 35, compared to the BCR-RA, the OHR-MUX has a smaller order of transistor count when a lower modulus is used. However, this order of transistor count starts to catch up with that of the BCR-RA when higher moduli are used. Nevertheless, the latency performance of the OHR-MUX is far more superior than that of the BCR-RA regardless of the modulus used. Compared to the BCR-CLA, the OHR-MUX is superior in both its order of transistor count and its latency. Although these values are only indicative, the vast difference in the latency performance suggests that a TC based DA-RNS system employing the OHC based modular adder can potentially be clocked at a much higher clock rate than a BC based DA-RNS system employing the BC based modular adder. This thus compensates for the TCRs longer bit-length. Taking further into consideration the latency due to the 2ⁿ scaling factor faced in a BC based DA-RNS system, the TC based DA-RNS system employing the OHC based modular adder is of even greater merit. However, a more detailed comparison performed based on actual implementations would be needed to determine exactly how much more superior the TC based DA-RNS system is.

### Advantages of System 1400

The following describes some advantages of the system 1400, particularly the system 1400 in the form of the TC based DA-RNS system.

The TC format is normally not popular as such a format appears to be not efficient due to its seemingly excessive number of bits required to represent typical data (e.g. 8-bit resolution). Hence, using the TC format with the RNS seems to be disadvantageous as it appears to nullify the RNS's benefit of having shorter word-lengths. Rather, such a benefit appears to be better achieved when the more conventional BC format is used for the DA-RNS implementation.

However, the inventors of the present invention have found that despite the seemingly higher number of bits required by the TC format, the TC format brings about unexpected and non-obvious advantages when used with the RNS. These advantages allow the TC format to be an attractive replacement for the BC format when used with a DA-RNS system. The use of the TC format enables the benefits of using the RNS with the DA technique to be truly realizable in a very efficient manner using simple circuit design.

One of the advantages is that when the TC format is used, the complications arising due to the 2ⁿ scaling factor encountered when using the BC format may be avoided. The accumulators required in a TC based DA-RNS system may hence be implemented in a much simpler manner (see FIG. 15) as compared to the accumulators required in a BC based DA-RNS system (see FIG. 2). In other words, the hardware circuit designs of the accumulators required in the TC based DA-RNS system are simpler. Because of the simpler operations required of the TC based DA-RNS system, overall performance gain can be obtained.

Furthermore, as compared to the BC based DA-RNS system, much simpler and yet, very efficient TCR modular arithmetic (for example, TCR modular addition) can be used in the TC based DA-RNS system. The modular addition or modular accumulation operations may be made even simpler and faster by using an OHC based modular adder. Using the OHC based modular adder overcomes the inefficient carry propagation as well as the complications due to the modulo operation associated with performing the modular addition with a BC based modular adder. Therefore, the operating speed of the OHC based modular adder is superior to that of the BC based modular adder. The OHC based modular adder may also be implemented using simple log shifter based circuits. When the OHC based modular adder is used, the TC based DA-RNS system outputs data encoded with the OHC format. Output data in this format may be converted to data in the BC format using a look up table (LUT) based encoder design, such as the binary encoder.

The performance of the TC based DA-RNS system may be further enhanced with an efficient implementation of the modular accumulators such that the TC based DA-RNS system can be operated at a higher clock rate as well as at higher bit-at-a-time (BATT) rates [1].

In addition, the DR of each residue digit in the RNS is bounded by its modulus. For example, with a [7,8,9] moduli set, the word-length of a residue digit in the TC format may just be 6, 7 and 8 for modulus 7, 8 and 9 respectively. These word-lengths are similar to the word-lengths of binary numbers that may be represented by the moduli set [7,8,9] if these numbers were encoded in the BC format (in particular, the binary numbers that may be represented by the moduli set [7,8,9] are in the range of [0,504)). Therefore, using the TC format with the RNS does not lead to excessive bit-lengths when compared to the BC based DA design.

As mentioned above, a TC based DA-RNS system comprising a DA-RNS based FIR filter is designed and implemented with its operation simulated using the PSPICE simulator. The simulation results validate the accuracy and practical feasibility of the TC based DA-RNS system. A broad performance comparison against the BC based DA system also shows that there is no penalty incurred in terms of transistor count and latency for the TC based DA-RNS system. Instead, there is a potential to run the TC based DA-RNS system at a higher clock rate or a higher BAAT rate (using parallel bit-serial operations) to further enhance the throughput performance of the system.

In the TC based DA-RNS system, one important practical consideration for using RNS based modular arithmetic is that a forward conversion is required to first convert the input signal (with levels coded in conventional numbers) to its residues. This is likely to be a costly operation and usually hinders the wide adoption of RNS in real world applications. This problem may be overcome by using the ADC 300 in the conversion unit 1402 of the TC based DA-RNS system as the data generated during the conversion by the ADC 300 are inherently output in the RNS pattern and with the TC format. As such, there is no extra overhead needed to convert the input signal to its RNS representation, and signal processing arithmetic operations on the input signal can be performed using the TCRs directly.

### REFERENCES

[1] White, S. A.; “Applications of distributed arithmetic to digital signal processing: a tutorial review,” ASSP Magazine, IEEE, vol. 6, no. 3, pp. 4-19, July 1989;
[2] Omondi, A.; and Premkumar, B.; Residue Number Systems, Theory and Implementation, Imperial College Press, Singapore, 2007
[3] Garcia, A.; Meyer-Base, U.; Lloris, A.; Taylor, F. J.; “RNS implementation of FIR filters based on distributed arithmetic using field-programmable logic,” Circuits and Systems, 1999. ISCAS '99. Proceedings of the 1999 IEEE International Symposium on, pp. 486-489 vol. 1, July 1999
[4] Vun, C. H.; Premkumar, A. B.; “RNS Encoding Based Folding ADC,” to be presented at ISCAS 2012, IEEE International Symposium on Circuits & Systems, Seoul, Korea 20-23 May 2012.
[5] Lim, K. P.; Premkumar, A. B.; “A modular approach to the computation of convolution sum using distributed arithmetic principles,” Circuits and Systems II: Analog and Digital Signal Processing, IEEE Transactions on, vol. 46, no. 1, pp. 92-96, January 1999
[6] Ramirez, J.; Garcia, A.; Meyer Base, U.; Taylor, F.; Fernandez, P. G.; Lloris, A.; “Implementation of RNS-Based Distributed Arithmetic Discrete Wavelet Transform Architectures Using Field-Programmable Logic,” VLSI Signal Processing, Vol. 33, No. 1-2, pp. 171-190, 2003
[7] Chren, W. A., Jr.; “One-hot residue coding for low delay-power product CMOS design,” Circuits and Systems II: Analog and Digital Signal Processing, IEEE Transactions on, vol. 45, no. 3, pp. 303-313, March 1998
[8] Pontarelli, S.; Cardarilli, G. C.; Re, M.; Salsano, A.; “Optimized Implementation of RNS FIR Filters Based on FPGAs”, Journal of Signal Processing Systems, Spinger, Online First™, 30 Sep. 2010
[9] Mano, M. M.; Kime, C. R.; Logic and Computer Design Fundamentals, Prentice Hall. USA, 1997
[10] Myung-Jun Choe et al., “An 8-b 100-MSample/s CMOS Pipelined Folding ADC”, IEEE Journal of Solid-State Circuits Vol. 36 No. 2 December 2001
[11] Robert C. Taft et al., “A 1.8V 1.6 GSample/s 8-b Self-Calibrating Folding ADC with 7.26 ENOB at Nyquist Frequency”, IEEE Journal of Solid-State Circuits Vol. 39 No. 12 December 2004
[12] Robert C. Taft et al., “A 1.8V 1.0 GS/s 10b Self-Calibrating Unified-Folding-Interpolating ADC with 9.1 ENOB at Nyquist Frequency”, IEEE Journal of Solid-State Circuits Vol. 44 No. 12 December 2009
[13] Phillip E. Pace, “High Resolution Encoding Circuit And Process For Analog To Digital Conversion”, U.S. Pat. No. 5,617,092, issued Apr. 1, 1997
[14]: Ferruccio Barsi, Piero Maestrini, “Error Detection and Correction by Product Codes In Residue Number Systems”, IEEE Transactions On Computers, Vol. C-23 No. 9 September 1974
[15] P. E. Pace et al., “A Preprocessing Architecture for Resolution Enhancement in High-Speed Analog-to-Digital Converters”, IEEE Transactions ON Circuits and Systems—II: Analog and Digital Signal Processing, Vol. 41 No. 6 June 1994

1-12. (canceled)

13. An analog-to-digital converter for converting an analog input signal into a digital signal, the analog-to-digital converter comprising a residue number system (RNS) converter for converting the input signal into a digital RNS representation based on a plurality of relatively prime moduli, and
wherein the RNS converter comprises for each said modulus:
a number of zero-crossing based folding circuits equal to the modulus, and configured to compare the input signal against a set of reference voltages to produce comparison outputs, the zero-crossing based folding circuits generating respective outputs as a function of the input signal based on a plurality of respective waveforms comprising zero-crossings at respective subsets of the reference voltages; and
a coding unit comprising respective comparators receiving the comparison outputs of the zero-crossing based folding circuits, the coding unit being configured to transform the outputs of the comparators into a plurality of bits encoding residues corresponding to the modulus.

14. An analog-to-digital converter according to claim 13, wherein for each said modulus,
each of the plurality of waveforms differs in phase from one other of the plurality of waveforms by a quantization level of the converter; and
each of the plurality of waveforms has zero-crossings spaced apart by a multiple of the quantization level, the multiple being equal to the modulus.

15. An analog-to-digital converter according to claim 13, wherein each of the plurality of waveforms is a differential-ended type waveform.

16. An analog-to-digital converter according to claim 13, wherein for each said modulus, the coding unit further comprises a plurality of exclusive OR circuits receiving the outputs of the comparators and configured to transform the outputs of the comparators into the plurality of bits encoding the residues corresponding to the modulus.

17. An analog-to-digital converter according to claim 13, wherein for each said modulus, the coding unit further comprises an encoder configured to receive the outputs of the comparators and generate from them an alternative digital representation of the input signal.

18. An analog-to-digital converter according to claim 17, wherein the alternative digital representation of the input signal is a thermometer code representation.

19. An analog-to-digital converter according to claim 17, wherein the alternative digital representation of the input signal is a one-hot code representation.

20. An analog-to-digital converter according to claim 16, wherein the RNS converter includes, for one or more additional moduli which are relatively prime with respect to each other and to said moduli, respective units for determining a representation of the input signal as additional residues based on the respective additional moduli, and a unit for comparing said residues and said additional residues to identify errors in said residues and/or correct errors in said residues.

21. An analog-to-digital converter according to claim 16, which further comprises a control unit configured to enable and disable the zero-crossing based folding circuits and the coding units for a subset of the plurality of moduli.
